(19) United States
(12) Patent Application Publication
(10) Pub. No.: US 2022/0367870 A1
(43) Pub. Date: Nov. 17, 2022

(54) ELECTRODE, ELECTROCHEMICAL CELL AND METHODS OF FORMING THE SAME

(71) Applicant: NATIONAL UNIVERSITY OF SINGAPORE, Singapore (SG)

(72) Inventors: Barbaros OEZYILMAZ, Singapore (SG); Cagdas CETIN, Singapore (SG); Chee Tat TOH, Singapore (SG); Irfan Haider ABIDI, Singapore (SG); Pieremanuele CANEPA, Singapore (SG); Xiao Feng LIM, Singapore (SG)

(73) Assignee: NATIONAL UNIVERSITY OF SINGAPORE, Singapore (SG)

(21) Appl. No.: 17/764,612

(22) PCT Filed: Sep. 30, 2020
(86) PCT No.: PCT/SG2020/050551

§ 371 Date: Mar. 29, 2022

(30) Foreign Application Priority Data
Sep. 30, 2019 (SG) 10201909125Y

(51) Int. Cl. H01M 4/525; H01M 4/505; H01M 10/0525; H01M 10/058; H01M 4/36; H01M 4/38

(52) U.S. Cl. CPC H01M 4/525; H01M 4/505; H01M 10/0525; H01M 10/058; H01M 4/366; H01M 4/386; H01M 4/387; H01M 2004/027

(57) ABSTRACT

Various embodiments may relate to an electrode. The electrode may include an electrode core including an electrode active material. The electrode may also include one or more monolayer amorphous films. Each of the one or more monolayer amorphous films may be a continuous layer surrounding the electrode core.

### CROSS-REFERENCE TO RELATED APPLICATION

This application claims the benefit of priority of Singapore application No. 10201909125Y filed Sep. 30, 2019, the contents of it being hereby incorporated by reference in its entirety for all purposes.

### TECHNICAL FIELD

Various aspects of this disclosure relate to an electrode. Various aspects of this disclosure relate to an electrochemical cell. Various aspects of this disclosure relate to a method of forming an electrode. Various aspects of this disclosure relate to a method of forming an electrochemical cell.

### BACKGROUND

Commercial lithium ion batteries use anodes containing natural graphite and synthetic graphite that are intercalated with lithium (Li). The resulting graphite intercalation compound can be expressed as LiₓC₆, where x is generally less than 1. The maximum amount of lithium ions that can be reversibly intercalated into the interstices between graphene planes of a perfectly crystalline graphite corresponds to x=1, defining a theoretical specific capacity of 372 mAh/g for graphite anodes.

In addition to graphite-based anodes, lithium alloys with a composition formula of LiₐA (A is a metal, and “a” corresponds to 0<a≤5) are of great interest due to their high theoretical capacity, e.g. Li_{4.4}Si, Li_{4.4}Sn, LiAl, and Li_{4.4}Ge with theoretical capacities of 4200 mAh/g, 990 mAh/g, 993 mAh/g, and 1623 mAh/g, respectively. Another example of charge carrier is sodium (Na) ions, which are a constituent of Na-ion batteries. Elements, including but not limited to silicon (Si), germanium (Ge), tin (Sn), lead (Pb), and antimony (Sb) could combine with sodium to form alloys with theoretical capacities of 954 mAh/g, 369 mAh/g, 847 mAh/g, 485 mAh/g, and 660 mAh/g, respectively. These alloying anode materials (negative electrode materials) are regarded as the most promising anode material candidates due to their high ionic insertion capacities and relatively low discharge potentials. However, these materials may undergo large volume expansion of up to 425% due to strain across the interface between the unlithiated crystalline core and the lithiated amorphous phase of active materials in the shell during repeated insertion and extraction of charge carrier ions, causing cracking of active particles, pulverization of electrode, loss of electrical contact with current collectors, and the formation of thick and non-uniform unstable solid electrolyte interface (SEI) layers. Both the solvent and electrolyte salts are thermodynamically unstable and subject to reduction on the anode surface. These SEI layers may passivate the anode surface and prevent the electrolytes from further decomposition. However, high volume expansion of alloying anode materials during electrochemical cycling may fracture the thick SEI layer, exposing a fresh surface of active material particles to the electrolyte during each cycle. The instability of the nonuniform SEI layer, mainly composed of lithium fluoride (LiF) and lithium carbonate (Li₂CO₃) for Li-ion batteries and sodium carbonate (Na₂CO₃) and sodium hydroxide (NaOH) for Na-ion batteries, may eventually result in significant capacity loss, short battery lifetime, and the drying out of the battery cells due to consumption of the electrolytes.

For the cathode (positive electrode) side of batteries, the capacity of positive electrode material (e.g. LiCoO₂) can be practically utilized only up to 50% of its theoretical capacity when the battery is charged at voltages >4.0 V, above which the positive electrode may become unstable due to reasons such as lattice defects, transition metal dissolution, structural degradation, which are associated with electrode-electrolyte side reactions. These side reactions could result in significant capacity degradation, short battery lifetime, and more importantly safety issues. As electrode-electrolyte side reactions occur on the surface of the active material, there is an urgent need for a surface coating that can protect the positive electrode from degradation.

### SUMMARY

Various embodiments may relate to an electrode. The electrode may include an electrode core including an electrode active material. The electrode may also include one or more monolayer amorphous films. Each of the one or more monolayer amorphous films may be a continuous layer surrounding the electrode core.

Various embodiments may relate to an electrochemical cell. The electrochemical cell may include an electrode as described herein. The electrochemical cell may also include a further electrode. The electrochemical cell may further include an electrolyte in contact with the electrode and the further electrode.

Various embodiments may relate to a method of forming an electrode. The method may include forming an electrode core including an electrode active material. The method may also include forming one or more monolayer amorphous films. Each of the one or more monolayer amorphous films may be a continuous layer surrounding the electrode core.

Various embodiments may relate to a method of forming an electrochemical cell. The method may include forming an electrode as described herein. The method may also include forming a further electrode. The method may further include providing an electrolyte in contact with the electrode and the further electrode.

### BRIEF DESCRIPTION OF THE DRAWINGS

The invention will be better understood with reference to the detailed description when considered in conjunction with the non-limiting examples and the accompanying drawings, in which:

FIG. 1 is a schematic showing an electrode according to various embodiments.

FIG. 2 is a schematic showing an electrochemical cell according to various embodiments.

FIG. 3 is a schematic showing a method of forming an electrode according to various embodiments.

FIG. 4 is a schematic showing a method of forming an electrochemical cell according to various embodiments.

FIG. 5 shows (left) a high resolution transmission electron microscopy (TEM) image of a monolayer amorphous film including hexagons and non-hexagons according to various embodiments; and (right) a fast fourier transform (FFT) of the left image showing a diffuse ring structure with no clear diffraction patterns, indicating the amorphous nature of the film according to various embodiments.

FIG. 6 is a plot of voltage potential (volts or V) as a function of capacity (in milliampere-hour per gram) showing the galvanostatic charge-discharge profiles of layered amorphous silicon oxycarbide (SiOC) films according to various embodiments.

FIG. 7 is a plot of normalized capacity (in percent or %) as a function of cycle number illustrating the variation in capacities of a polymer-derived thick amorphous material coated active material particle as well as two layered two dimensional (2D) amorphous material particles according to various embodiments at a current density of 1 A/g over a potential range of 0.01 V to 1.5V according to various embodiments over time.

FIG. 8 shows (left) an optical image of a bubble test in which some holes are covered by monolayer amorphous carbon (MAC) films according to various embodiments and gas is introduced such that the monolayer amorphous carbon (MAC) films each forms a bulge; and (right) an atomic force microscopy (AFM) image showing the bulging of the monolayer film according to various embodiments after removal from a high pressure gas chamber.

FIG. 9 shows (left) an optical image showing crack propagation along grain boundaries of graphene after indentation; and (right) an optical image of a monolayer amorphous carbon (MAC) film according to various embodiments showing lack of crack propagation after indentation.

FIG. 10A shows (above) an atomic force microscopy (AFM) image of a suspended monolayer amorphous carbon (MAC) film according to various embodiments after an indentation is made on the film; and (below) a graph of height (in nanometers or nm) as a function of distance (in nanometers or nm) showing the corresponding height profile which shows an indentation peak after the AFM is pulled out of the monolayer amorphous carbon (MAC) film.

FIG. 10B shows (above) another atomic force microscopy (AFM) image of the suspended monolayer amorphous carbon (MAC) film according to various embodiments after a second indentation is made on the film (on the right of the first indentation); and (below) a graph of height (in nanometers or nm) as a function of distance (in nanometers or nm) showing the corresponding height profile which shows a second indentation peak after the AFM is pulled out of the monolayer amorphous carbon (MAC) film.

FIG. 10C shows a three-dimensional atomic force microscopy (AFM) image of the suspended monolayer amorphous carbon (MAC) film according to various embodiments with two indentations.

FIG. 11A is a plot of current (in amperes or A) as a function of voltage (V) showing the current-voltage (IV) curve of a monolayer amorphous film according to various embodiments.

FIG. 11B is a plot of count (i.e. distribution) as a function of resistivity (in ohms-centimeters or Ω-cm) showing a histogram of the measured resistivity values for monolayer amorphous films of a particular crystallinity (C) value according to various embodiments.

FIG. 12 is a plot of intensity (in arbitrary units) as a function of Raman shift (in per centimeter or cm⁻¹) showing the Raman spectra of a monolayer amorphous film according to various embodiments as well as nanocrystalline graphene.

FIG. 13 is a plot of intensity (in arbitrary units) as a function of binding energy (in electron-volts or eV) showing the X-ray photoelectron spectroscopy (XPS) spectrum of an one atomic layer thick (6 Angstroms) amorphous film with a sp³/sp² ratio of 20% according to various embodiments.

FIG. 14A is a plot of intensity (in arbitrary units) as a function of 2 Theta (in degrees) showing the X-ray diffraction (XRD) spectrum of a layered amorphous silicon oxycarbide (SiOC) film on an active material according to various embodiments, while the inset shows the amorphous characteristics of the layered amorphous silicon oxycarbide (SiOC) film.

FIG. 14B is a scanning electron microscopy (SEM) image of layered amorphous silicon oxycarbide (SiOC) film coated active material particle according to various embodiments.

FIG. 15A shows (above) a plot of relative intensity (in arbitrary units or a.u.) as a function of binding energy (in electron volts or eV) illustrating the X-ray photoelectron spectroscopy (XPS) survey spectrum of a layered amorphous silicon oxycarbide (SiOC) film on a silicon (Si) particle; and (below) a plot of relative intensity (in arbitrary units or a.u.) as a function of binding energy (in electron volts or eV) illustrating the X-ray photoelectron spectroscopy (XPS) survey spectrum of pristine silicon (Si) particles.

FIG. 15B is a plot of intensity (in arbitrary units or a.u.) as a function of binding energy (in electron volts or eV) illustrating high resolution deconvoluted X-ray photoelectron spectroscopy (XPS) spectrum of layered amorphous silicon oxycarbide (SiOC) film according to various embodiments in silicon (Si) 2p region.

FIG. 16A is a schematic illustrating a monolayer amorphous film according to various embodiments surrounding an active material particle according to various embodiments.

FIG. 16B is a schematic depicting (above) a silicon active material particle coated with a conventional coating; and (below) a silicon active material particle coated with a monolayer amorphous film according to various embodiments under lithiation, delithiation and cycling.

FIG. 17 is a plot of indentation load (in micro-Newtons or μN) as a function of indentation depth (in nanometers or nm) shows the load-depth curves of a thick amorphous silicon oxycarbide (SiOC) film coating on active material particles.

FIG. 18 is a plot of the imaginary part of impedance (in ohms or Ω) as a function of the real part of impedance (in ohms or Ω) showing the electrochemical impedance spectroscopy (EIS) of a thick amorphous coating on active material particles.

FIG. 19A is a plot of efficiency (in percent or %) as a function of cycle number illustrating the coulombic efficiency of the layered amorphous silicon oxycarbide (SiOC) coated electrode material according to various embodiments.

FIG. 19B is a plot of normalized capacity (in percent or %) as a function of cycle number illustrating the cycling stability of the layered amorphous film coated electrode material according to various embodiments.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, and logical changes may be made without departing from the scope of the invention. The various embodiments are not necessarily mutually exclusive, as some embodiments can be combined with one or more other embodiments to form new embodiments.

Embodiments described in the context of one of the methods or electrodes/cells are analogously valid for the other methods or electrodes/cells. Similarly, embodiments described in the context of a method are analogously valid for an electrode/cell, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

The electrode or cell as described herein may be operable in various orientations, and thus it should be understood that the terms “top”, “bottom”, etc., when used in the following description are used for convenience and to aid understanding of relative positions or directions, and not intended to limit the orientation of the electrode or cell.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance.

As used herein, the term “and/or” includes any and all combinations of one or more of the associated listed items.

Various embodiments may seek to address to abovementioned issues.

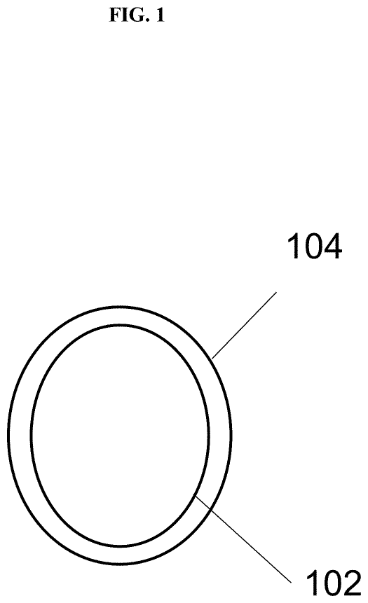

Various embodiments may relate to an electrode including one or more monolayer amorphous films. FIG. 1 is a schematic showing an electrode according to various embodiments. The electrode may include an electrode core 102 including an electrode active material. The electrode may also include one or more monolayer amorphous films (MAFs) 104. Each of the one or more monolayer amorphous films 104 may be a continuous layer surrounding the electrode core 102.

For avoidance of doubt, FIG. 1 is not intended to limit the shape, size, orientation etc. of the electrode or its components. For instance, while FIG. 1 shows an electrode core 102 with a circular cross-sectional area, various embodiments may be of any suitable shape. In addition, while FIG. 1 shows one monolayer amorphous film, various embodiments may relate to an electrode including a plurality of monolayer amorphous films.

In the current context, each of the one or more monolayer amorphous films 104 surrounding the electrode core 102 may refer to the one or more monolayer amorphous films 104 covering all possible outer surfaces of the electrode core 102. In other words, a coating including the one or more amorphous films 104 may cover an entirety of the electrode core 102.

In the current context, an “amorphous” solid may refer to a solid that lacks the long-range order that is characteristic of a crystal.

In the current context, the term “monolayer” may refer to an one-atom thick layer.

The monolayer amorphous films may alternatively be referred to as two -dimensional (2D) amorphous films. A monolayer amorphous film may have a mixture of hexagonal and non-hexagonal rings. Non-hexagonal rings may be in a form of 4-, 5-, 7-, 8-, 9-membered rings etc. The rings may be fully connected to one another, forming a network of polygons in a large area film whose scale is at least in microns. Crystallinity (C) may refer to a degree of structural order in a solid, and may be measured based on a ratio of the number of hexagonal rings to the total number of (polygonal) rings (including hexagonal, heptagonal, octagonal, pentagonal rings etc.). For instance, when a film has a crystallinity of 80%, the number of hexagonal rings divided by the total number of rings is 0.8. In other words, the crystallinity of a films may be obtained by a ratio of hexagonal rings to the total number of rings multiplied by 100. In the current context, a monolayer amorphous film may be a film having a crystallinity equal or less than 80% (C≤80%). In various embodiments, such as an amorphous MAC film, the crystallinity may be equal or greater than 50% (C≥50%). The crystallinity of the one or more monolayer amorphous films may be tuned to any suitable value between 50% and 80% (inclusive of both end values). In contrast, perfect graphene has a crystallinity of 100%.

As mentioned above, in various embodiments, the one or more monolayer amorphous films 104 may be a plurality of monolayer amorphous films. The plurality of monolayer amorphous films may form a stack. The different monolayers may not be covalently bonded to one another. Instead, there may be van der Waals forces between the different monolayers within the stack. In contrast, for a conventional amorphous film, there may be covalent bonding throughout the entire thickness of the film.

In various embodiments, the individual monolayers in the stack of plurality of monolayer amorphous films may have the same crystallinity as when they are free-standing.

In various embodiments, the one or more monolayer amorphous films 104 may be electrically insulating. In various embodiments, the electrical conductivity of the one or more monolayer amorphous films 104 may be tuned. For a stack of monolayer amorphous films, the electrical conductivity of the stack may be modified if the electrical conductivity of the individual monolayer amorphous films 104 are modified. In various embodiments, the electrical conductivity of the one or more monolayer amorphous films e.g., MAC, the electrical conductivity along a plane parallel to the surfaces of the monolayer(s) may be negligible, but there may be observable conductivity along the perpendicular direction.

In various embodiments, the electrode core 102 may be a particle, which may alternatively be referred to as an active material particle, or electrode active particle. In various embodiments, the electrode may include a plurality of electrode cores, with one or more monolayer amorphous films (MAFs) surrounding each electrode core 102.

The one or more monolayer amorphous films 104 may accommodate volume expansion of the electrode core 102 and mitigate pulverization. Further, the one or more monolayer amorphous films 104 may act as a buffer layer between the electrode core 102 and electrolyte, thereby isolating the electrode core 102 and prevent the electrode core 102 from being directly exposed to the electrolyte, therefore significantly preventing the formation of thick and unstable solid electrolyte interface (SEI) layers during repeated insertion/extraction of ions, and the degradation of positive active material. The one or more monolayer amorphous films 104 may also provide protection of active material particle surface from air oxidation.

In various embodiments, the electrode active material may be an anode active material. The anode active material may be any suitable material to be used as an anode, including, but is not limited to any one material selected from a group consisting of silicon (Si), tin (Sn), aluminum (Al), and germanium (Ge).

In various embodiments, the electrode active material may be a cathode active material. The cathode active material may be any suitable material to be used as a cathode, including, but is not limited to any one material selected from a group consisting of lithium cobalt oxide (LiCoO₂), lithium manganese oxide (LiMn₂O₄), lithium nickel cobalt manganese oxide (LiNiMnCoO₂), lithium iron phosphate (LiFePO₄), lithium nickel cobalt aluminum oxide (LiNiCoAlO₂), and lithium nickel manganese cobalt oxide (LiNiCoMnO₂).

In various embodiments, the one or more monolayer amorphous films 104 may be monolayer amorphous carbon (MAC) films. Each monolayer of MAC may be about 0.6 nm. For other monolayer amorphous films, each monolayer may be equal to or above 0.3 nm.

In various embodiments, a ratio of a number of hexagonal carbon rings to a total number of hexagonal carbon rings and non-hexagon carbon rings (i.e. the total number of polygonal carbon rings) present in the one or more monolayer amorphous films 104, e.g. one or more monolayer amorphous carbon (MAC) films, may be equal to 0.8 or less, e.g. 0.6.

In various embodiments, an average diameter of the hexagonal carbon rings may be any value selected from a range from 0.76 Angstroms to 2.3 Angstroms. An average diameter of the non-hexagonal carbon rings may be any value selected from a range from 0.76 Angstroms to 2.3 Angstroms.

In various other embodiments, the one or more monolayer amorphous films 104 may be layered amorphous silicon oxycarbide (SiOC) films or layered amorphous silicon carbon nitride (SiCN) films.

In various embodiments, the one or more monolayer amorphous films 104 may include one or more monolayer amorphous carbon (MAC) films and one or more layered amorphous silicon oxycarbide (SiOC) films. The one or more monolayer amorphous carbon (MAC) films may form an alternating stack arrangement with the one or more layered amorphous silicon oxycarbide (SiOC) films. A MAC film may be between two neighbouring SiOC films. A SiOC film may be between two neighbouring MAC films.

In various embodiments, each of the one or more monolayer amorphous films 104 may include in-plane bonds.

In various embodiments, the one or more monolayer amorphous films 104 may have a thickness of a value selected from a range from 0.3 nm to 3 nm. Various embodiments may be beneficial due to diffusivity of lithium ions and due to elasticity.

In various embodiments, the one or more monolayer amorphous films 104 may have an electrical resistivity of a value selected from a range from 10⁻² Ωcm to 10³ Ωcm.

In various embodiments, the one or more monolayer amorphous films 104 may be configured to withstand up to a percentage deformation selected from a range from 1% to 20% without fracturing.

In various embodiments, a bond ratio of sp² bonds to a total of sp² and sp³ bonds in the one or more monolayer amorphous films, e.g. MAC film(s), may be 0.8 or greater, e.g. 0.9 or greater. In other words, various embodiments may contain equal to or more than 80% or 90% of sp² bonds as a percentage of the total number of bonds, and less than 20% or less than 10% of sp³ bonds as a percentage of the total number of bonds. In contrast, a conventional amorphous carbon (C) film may include randomly hybridized carbon with sp³ and sp² configurations and which contains contaminations such as hydrogen, oxygen and nitrogen. Such a conventional amorphous carbon film may not grow in layer-by-layer (i.e. two-dimensional or 2D) form, but may be grown in three-dimensional or 3D due to sp³ content (bonded layers).

In contrast, in various embodiments, the one or more monolayer amorphous films 104 may include predominantly sp² bonds. In various embodiments, a bond ratio of sp³/sp² present in the one or more monolayer amorphous films may be 0% to 20% (i.e. 0.2 or less, e.g. 0.1 or less).

In various embodiments, the one or more monolayer amorphous films 104 may have a Young Modulus of a value selected from a range from 50 GPa to 500 GPa.

In various embodiments, an adhesion force of the one or more monolayer amorphous films 104 to a surface of the electrode core 102 may be of a value greater or equal to 200 Jm⁻².

In various embodiments, the one or more monolayer amorphous films 104 may include a plurality of monolayer amorphous films. In various embodiments, a structure of a first monolayer amorphous film of the plurality of monolayer amorphous films 104 may be different from a structure of a second monolayer amorphous film of the plurality of monolayer amorphous films 104. In various embodiments, a property of the first monolayer amorphous film of the plurality of monolayer amorphous films 104 may be different from a property of the second monolayer amorphous film of the plurality of monolayer amorphous films 104.

In various embodiments, the electrode may be configured to exhibit an initial coulombic efficiency of at least 84%.

In various embodiments, the electrode may be configured to exhibit cycling stability greater than 85% at 0.35 C for 50 cycles.

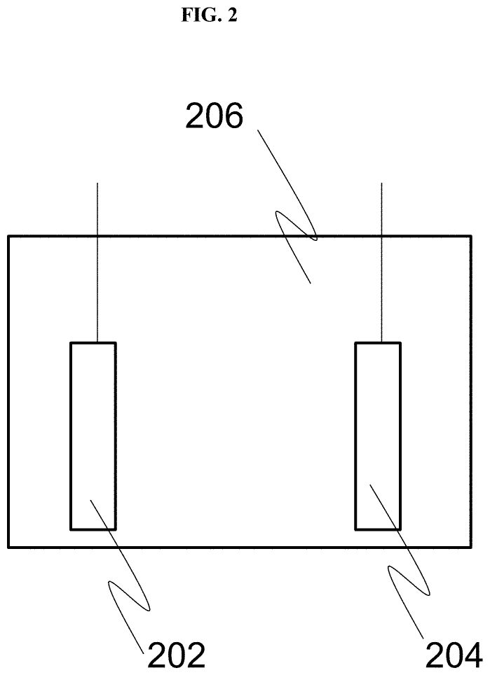

FIG. 2 is a schematic showing an electrochemical cell according to various embodiments. Various embodiments may relate to an electrochemical cell having one or both electrodes including the monolayer amorphous film(s).

The electrochemical cell may include an electrode 202 as described herein, i.e including the one or more monolayer amorphous films. The electrochemical cell may further include a further electrode 204. The electrochemical cell may also include an electrolyte 206 in contact with the electrode 202 and the further electrode 204. The electrolyte 206 may be in contact with the one or more monolayer amorphous films of the electrode 202.

In various embodiments, the further electrode 204 may include a further electrode core including a further electrode active material. The further electrode 204 may include one or more further monolayer amorphous films. Each of the one or more further monolayer amorphous films may be a continuous layer surrounding the further electrode core. The one or more further monolayer amorphous films may cover all possible outer surfaces of the further electrode core. The electrolyte 206 may be in contact with the one or more further monolayer amorphous films of the further electrode 204.

The electrolyte 206 may for instance include lithium hexafluorophosphate (LiPF₆) solution, lithium tetrafluoroborate (LiBF₄) solution, or lithium perchlorate (LiClO₄) solution.

In various embodiments, the electrode 202 may be a cathode (positive electrode), while the further electrode 204 may be an anode (negative electrode). In various other embodiments, the electrode 202 may be an anode (negative electrode), while the further electrode 204 may be a cathode (positive electrode). In various embodiments, the further electrode 204 may include a plurality of further electrode cores, the plurality of further electrode cores including the further electrode active material.

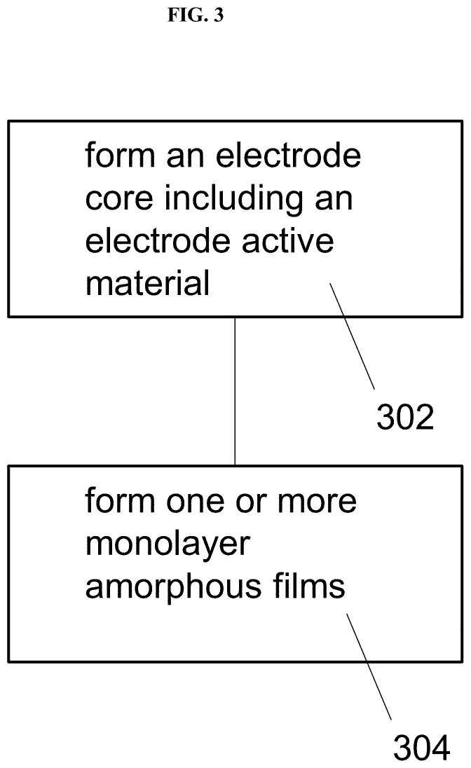

FIG. 3 is a schematic showing a method of forming an electrode according to various embodiments. The method may include, in 302, forming an electrode core including an electrode active material. The method may also include, in 304, forming one or more monolayer amorphous films. Each of the one or more monolayer amorphous films may be a continuous layer surrounding the electrode core.

In various embodiments, the one or more monolayer amorphous films may be formed by spark plasma sintering (SPS), plasma synthesis, and/or hydrothermal processes.

In spark plasma sintering (SPS), one or more precursors and particles of the electrode active material may be dispersed in a fluid or liquid to form a suspension. The suspension may be sonicated and subsequently dried, before current pulses are passed through the particles which are coated with the one or more precursors to form discharge plasma and to generate Joule heating, thereby forming the one or more monolayer amorphous films. The one or more monolayer films may be formed at a temperature equal to or less than 400° C., which may be lower than conventional methods. Joule heating may enable self-limiting growth for forming the one or more monolayer amorphous films.

Plasma synthesis may be based on laser-driven chemical vapor pyrolysis. One or more chemical precursors may be introduced, and infrared radiation (e.g. emitted by a laser) may be provided so that the one or more chemical precursors is absorbed onto particles of the electrode active material. The absorbed one or more chemical precursors may be thermally decomposed, and may subsequently form the one or more monolayer amorphous films. The formation of the one or more monolayer amorphous films may be assisted via collisions of incoming chemical precursors onto the particles of the electrode active material.

In a hydrothermal process, one or more precursors, e.g. a carbonaceous precursor such as glucose, and particles of the electrode active material may be dispersed in a fluid or liquid to form a suspension. The suspension may be heated up in an autoclave. The one or more precursors may be initially physisorbed onto the particles, and heat may be used to chemically attach the one or more precursors to the particles. A temperature in the range from 40° C. to 70° C. may be used to evaporate the fluid or liquid and for chemically attaching the one or more precursors to the particles. SPS may subsequently be used to form the one or more monolayer amorphous films.

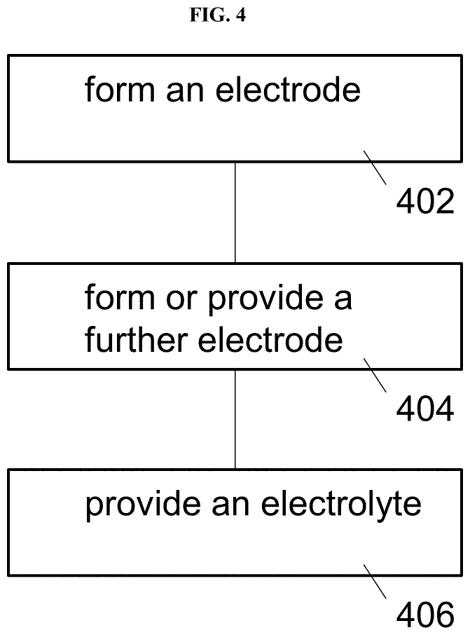

FIG. 4 is a schematic showing a method of forming an electrochemical cell according to various embodiments. The method may include, in 402, forming an electrode as described herein, i.e. including one or more monolayer amorphous films. The method may also include, in 404, providing or forming a further electrode. The method may further include, in 406, providing an electrolyte in contact with the electrode and the further electrode.

For avoidance of doubt, FIG. 4 is not intended to limit the sequence of the various steps. For instance, in various embodiments, the electrode and the further electrode may be formed or provided in the cell first before the electrolyte is introduced. In various other embodiments, the electrolyte may be introduced first before the electrode and the further electrode are placed in the cell.

In various embodiments, the further electrode may include a further electrode core including a further electrode active material. The further electrode may include one or more further monolayer amorphous films. Each of the one or more further monolayer amorphous films may be a continuous layer surrounding the further electrode core. The one or more further monolayer amorphous films may cover all possible outer surfaces of the further electrode core. The electrolyte may be in contact with the one or more further monolayer amorphous films of the further electrode.

The coating of active material particles with the monolayer amorphous films may accommodate volume expansion of inner particles to mitigate pulverization and may act as a buffer layer between the electrode active material and electrolyte to isolate the electrode active particles from being directly exposed to the electrolyte, therefore significantly preventing the formation of thick and unstable SEI layers during repeated insertion/extraction of ions, and the degradation of positive active material. The coating may also provide protection of active material particle surface from air oxidation.

Until now, existing work on active materials has not yet met the requirements for commercial applications because of unsatisfactory battery lifetime associated with electrode pulverization and degradation. Other coating materials including graphene, polymer-derived carbon, metal oxides such as aluminum oxide (Al₂O₃), zirconium oxide (ZrO₂) are unable to solve existing issues relating to both the positive electrode and the negative electrode. Various embodiments may relate to continuous layered amorphous films, which are grown at much lower temperatures, to allow selective diffusion of only charge carriers (e.g. lithium ions (Li⁺), sodium ions (Na⁺), potassium ions (K⁺)). The monolayer amorphous films may act as a chemically and mechanically stable barrier for the positive electrode and/or the negative electrode.

Currently, battery electrodes may include polymer-derived carbon shell on active material particles. This carbon shell acts as a selective membrane. Initial capacity values of such a structure are typically between 1000 mAh/g to 1500 mAh/g, suggesting good performance on the ion diffusion. However, active materials coated with this type of carbon in shell typically exhibit rapid capacity drop to <50% of their initial capacity value within <200 cycles. The capacity failure that occurs at less than 200 cycles may be due to poor ion selectivity. The shell may allow other electrolyte salts through the membrane that causes electrode-electrolyte side reactions and failure. Carbon coating is synthesized through thermal decomposition of a carbonaceous precursor. The resulting carbon shell is at least 10 nm-thick, non-uniform, and unsustainable during volume expansion of inner particles during insertion and extraction of ions due to its inherent brittle characteristics. Moreover, the thick carbon coating limits ionic diffusion into the inner particle. Overall, the polymer-derived carbon shell structure undergoes uneven volume expansion with pulverization, causing rapid capacity decay.

The pyrolysis of carbonaceous precursors results in carbon coating with high sp³ to sp² ratio of up to 80%. These coatings are brittle due to high ratio of sp³ to sp², leading to fracture and pulverization of active materials in early cycles. In contrast, various embodiments may have a high ratio of sp² to sp³. Various embodiments may have a high sp² percentage of the total bonds in the range of 80% to 100%, which makes the material stretchable and be resistant to strain-induced deformation.

Transformation of these precursors into two-dimensional (2D) polymer-derived carbon shell films may require pyrolysis of polymers or monomers with cross-linking agents at temperatures higher than 700° C. The possibility of electrochemically inactive and electrically insulating metal-ceramic formation at the interface between inner electrode material and carbon shell may be inevitable due to high temperature pyrolysis. In contrast, various embodiments may be grown at much lower temperatures, eliminating the risk of metal-ceramic formation.

Various embodiments may allow for a more uniform diffusion barrier coating, which may prevent or reduce formation of electrochemically inactive and low adhesion native oxide on particles.

Graphene is a known 2D carbon structure. However, graphene is not a suitable solution as a selective membrane. The ratio of the number of hexagonal rings to the total number of rings (including hexagonal, heptagonal, octagonal, pentagonal rings etc.) is a measure of crystallinity (or amorphicity), C. Non-hexagons are in a form of 4-, 5-, 7-, 8-, 9-membered rings etc. Perfect graphene has a pure hexagonal network, where crystallinity (C) is equal to 1. A 2D amorphous film may have a crystallinity equal to or less than 80% (C≤80%) but equal to or more than 50% (C≥50%), where non-hexagons are distributed within the hexagonal matrix. The pore diameter within each hexagonal ring for graphene is about 1.4 Å, which is much smaller than the diameter of charge carriers, which limits ionic diffusion into inner active material particles, resulting in lower battery capacity. In contrast, various embodiments may have 7 or 8 membered rings with the bigger pore diameter, which allows efficient ionic diffusion into the inner particles to maintain high capacity.

Graphene cannot be synthesized on battery electrode materials with layer uniformity and high sp² ratio. The synthesis of graphene requires high temperatures. Further, graphene has inherent nanoscale line defects, known as grain boundaries and grain-boundary triple junctions that lead to significant brittle behavior of a graphene-based shell coating in the shell. The graphene -based shell coating may be unable to withstand severe volume expansion of the inner particles. In contrast, various embodiments relating to 2D amorphous films may be elastic and may be strongly bonded to the surface of the electrode core including the electrode active material. Various embodiments may be suitable as coating on the surface of the electrode core including the electrode active material. The excellent mechanical property may be due to the lack of grain boundaries present in the 2D amorphous films.

Unlike graphene that has the electrical resistivity value of ˜10⁻⁶ Ω-cm, the resistivity of the 2D amorphous films may be tunable with the ratio of hexagons to non-hexagons and may have the range from 10² to 10¹⁰ Ω-cm. The atomically thin 2D amorphous films may protect the electrolyte from further reduction by blocking electron transport.

Likewise, metal oxide coatings such as aluminum oxide (Al₂O₃) coatings may also not be suitable as charge carrier selective membranes. Atomic layer deposition (ALD) is employed to deposit coatings of inorganic metal oxides such as aluminum oxide (Al₂O₃), zirconium oxide (ZrO₂) on the surface of silicon (Si) particles in an attempt to prevent direct electrolyte contact of the anode and cathode materials, thereby stabilizing the SEI layer and limiting electrode-electrolyte interface side reactions. Metal oxide coatings on active electrode material exhibits up to 1500 mAh/g initial capacity value, suggesting moderate amount of ions diffusion. However, these metal oxides are brittle materials with limited durability against volume expansion of inner electrode particles and therefore cannot resist cracking upon volume expansion of inner active material particle, resulting in rapid capacity loss to <60% of their initial value within 150 cycles. In contrast, the elastic nature of 2D amorphous films according to various embodiments may accommodate volume expansion. The metal oxide coatings may also lack uniformity due to nature of ALD growth mechanism, resulting in only partial coverage of active material particles. Even if this is achieved, such metal oxides suffer from low ionic conductivity, limiting capacity of materials and energy densities of batteries.

Thick silicon oxycarbide (SiOC) shells are used as selective membranes for silicon active material-based batteries. The precursor and the cross-linking agent are cross-linked at temperatures less than 400° C., followed by high temperature pyrolysis of cross-linked polymers to form the SiOC coating (˜10 nm-thick) on active material particles. However, this synthesis involves multiple steps with batch to batch process and formation of electrochemically inactive native oxide. Furthermore, the resulting thick SiOC coating has a brittle nature due to high sp³ to sp² ratio, making this material unsuitable as a coating in batteries due to pulverization. Even if this SiOC shell works for Li ions permeation, the lack of elasticity of this SiOC shell may lead to structural failure and rapid capacity losses, associated with pulverization. In contrast, various embodiments may relate to monolayer amorphous films, such as layered amorphous silicon oxycarbide (SiOC) films, which has a high sp² to sp³ ratio. The high sp² to sp³ ratio may allow for a film structure with superior elasticity.

Specific energy densities of the existing battery technologies may range from 100 Wh/kg to 265 Wh/kg. However, this range is well below energy density requirements of a wide range of technological advancements, including electrified aircrafts, electric trucks, and high-performance consumer electronic devices that typically require an energy density of at least 320 Wh/kg. Battery makers are looking to replace existing graphite-based technology into high capacity active materials such as silicon (Si) as the current energy densities of existing technologies are not enough to power a wide range of devices. Conventionally, the overall weight of devices is high due to low volumetric energy densities in the range of 200-400 Wh/l. Silicon may be of key importance to enable next generation batteries that can deliver energy densities up to 400 Wh/kg to make electric mobility technologies and high-performance consumer devices workable. Critical challenges facing silicon-based electrodes include rapid capacity decay and battery cell failure due to pulverization, thick unstable SEI layer, electrode-electrolyte interface side reactions. Such critical issues have not been solved to put this technology into practice. Various embodiments may address or solve technical issues of poor ion selectivity, electrode-electrolyte side reactions, unstable SEI growth, and structural integrity of anode and cathode materials, in particular high capacity active materials, by employing layered structure 2D amorphous composite films. Various embodiments may enable the emergence of next generation batteries with high energy densities in the range of 600-950 Wh/l to power advanced technologies.

Methods to form monolayer amorphous carbon films and layered amorphous silicon oxycarbide (SiOC) films are described herein. However, these methods may also be adapted to form any other suitable monolayer amorphous films.

Various embodiments may use spark plasma sintering (SPS) to convert the precursors into thin monolayer amorphous carbon (MAC) or layered amorphous (SiOC) structures at fast speeds and low temperatures by passing pulsed electric currents through the materials. Carbonaceous precursors containing suspension may be first coated on the active material particles and dried. During SPS, the current pulses may flow through the precursor-coated particles, thereby generate discharge plasma, and provide Joule heating which is directly applied to the precursor coated active material particles in an efficient manner. The discharge plasma generated by current sparks between the particles transform the precursors into monolayer amorphous films.

For forming two-dimensional layered amorphous silicon oxycarbide (SiOC) films, silane-based precursors (e.g. trimethoxymethylsilane (TMMS), polydimethylsiloxane, phenyltriethoxysilane, polysiloxane, methyltrimethoxysilane, vinyltrimethoxysilane, phenyltrimethoxysilane) may be used. Trimethoxymethylsilane (TMMS) is described as an example. 1 mL of trimethoxymethylsilane precursor is added into a suspension of active material particle in a solvent. Subsequently, the resulting suspension is sonicated up to 2 hours. The dispersion of TMMS precursor coated active material particles in a solvent may then be atomized using spray gun. The atomized droplets may form coating on a current collector (e.g. including copper (Cu), aluminum (Al), nickel (Ni), molybdenum (Mo)). Spark Plasma Sintering (SPS) may be used to convert the precursor into SiOC. The trimethoxymethylsilane precursor subjected to SPS at temperatures up to 1100° C. in an inert environment for up to 90 minutes may form uniform monolayer amorphous SiOC films. During SPS process, the current pulses passing through the precursor-coated active material particles may create discharge plasma and generate Joule heat which is directly applied to the precursor coated active material particles. This process is based on the treatment of precursor coated active material particles under uniaxial pressure for which direct current pulses are applied. Unlike other pyrolysis mechanism, high-electric currents flowing through the structure may give rise to percolation effects of the high current into the sample and electromigration across the interfaces during SPS. The direct Joule heating mechanism may provide sufficient energy directly to the precursors. This locally distributed energy may enable in-plane bond formation of layered 2D amorphous SiOC coating on active material particles at much lower temperatures ≤400° C. over a very short period of time (i.e. less than 30 minutes), as compared to other standard thermal approaches where the required temperature for pyrolysis exceeds 900° C. over more than 2 hours. The transformation of organosilicon polymers (e.g. silane-based precursor) into SiOC in an inert environment may proceed via a free radical reaction mechanism enabled by electromigration, which is a structure formation mechanism different from other standard thermal assisted formation. Under the SPS process, high electric current with Joule heating breaks off Si—H, C—H, Si—C, Si—CH₃ bonds to form the SiOC coating on active material particles. Unlike other thermal process, Joule heat generation with high-current flow may enable self-limiting growth, due to the inability of precursors to react with themselves. This self-limiting growth mechanism with SPS may give rise to layered 2D amorphous SiOC films.

Furthermore, standard thermal approaches necessitate the use of either cross-linking agent or catalyst for the polymerization of precursors to transform into amorphous SiOC. The necessity of such cross-linking agent is bypassed with SPS due to Joule heating that directly enables the conversion of precursors into layered amorphous 2D SiOC.

For forming monolayer amorphous carbon (MAC) films, carbonaceous precursors can be used. The use of sucrose may be used as one example of a carbonaceous precursor. Active material particle is dispersed in solvent (e.g. ethanol) using sonication. After the precursor is added to the dispersion, the mixture is sonicated for another 1 hour. Then, SPS is used to carbonize the precursor to form MAC coating on active electrode particles at temperatures ≤400° C. for less than 30 minutes, compared to standard thermal processes that requires temperatures higher than 700° C. for at least 2 hours. Unlike other standard thermal approaches, SPS may allow high-direct current flow through the precursor coated active electrode material and may generate Joule heating on the particles. This feature may enable self-limiting growth, due to the limiting of the precursor reacting with itself This mechanism may give rise to monolayer amorphous carbon (MAC) film formation on active electrode particles without the need of catalyst or cross-linking agent (e.g. silicon (Si), tin (Sn), lithium iron phosphate (LiFePO₄)).

Plasma synthesis is based on laser-driven chemical vapor pyrolysis, in which the infrared radiation emitted by a laser is absorbed by a flow of chemical precursors, resulting in their thermal decomposition, followed by uniform monolayer growth on active material particles by collision assisted process. A very thin layer of amorphous carbon may be coated on particles using a non-thermal, C₂H₂ containing radio frequency (rf) plasma. The rf power may be set between the range of 50-60 W to form the monolayer amorphous carbon films on the active material particles. Electrochemically inactive metal-ceramic formation may be formed at the interface between amorphous carbon and inner active material particle as a consequence of the reaction of hydrocarbon radicals with crystalline particles.

For hydrothermal processes, carbonaceous particles may generally be used. Glucose is described herein as one example. The suspension solution of the active material particle and the precursor may be transferred to an autoclave. Monolayer amorphous 2D materials may be assembled on active electrode materials by using tethering by aggregation and growth in hydrothermal environment. During this process, precursor may initially be physisorbed from a suspension solution onto the surface of active electrode material. Then, heating step may be applied to chemically attach this precursor to the surface of the particles. The resulting powder solution may be rinsed to remove any existing multilayers from the surface. During heating step, temperature between 40° C. and 70° C. may be enough for complete solvent evaporation and chemisorption to form self-assembled layered amorphous 2D materials on the particles. The layered amorphous 2D materials can be bonded in-plane to form a uniform and continuous film by using SPS.

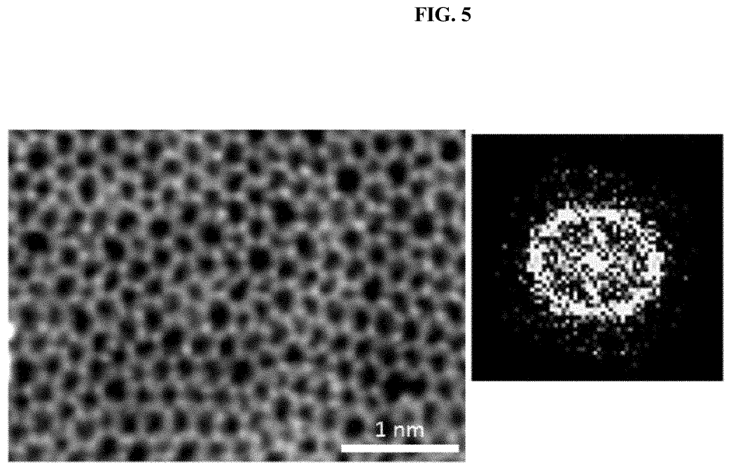

FIG. 5 shows (left) a high resolution transmission electron microscopy (TEM) image of a monolayer amorphous film including hexagons and non-hexagons according to various embodiments; and (right) a fast fourier transform (FFT) of the left image showing a diffuse ring structure with no clear diffraction patterns, indicating the amorphous nature of the film according to various embodiments. The left image shows the structure include hexagons and non-hexagons with 4, 5, 6, 7, 8 membered rings, indicating that the film may act as a preferential ion diffusion membrane by having tunable pore size greater than the diameter of charge carrier ions, and may simultaneously block the diffusion of electrolyte molecules and gases to reduce or prevent further SEI growth in the interface and on the surface. Based on the high density of rings that have more than 6 members, ion diffusion of the monolayer amorphous film may be better than existing 2D materials. The energy requirements for ionic diffusion through the rings may be reduced by functionalization.

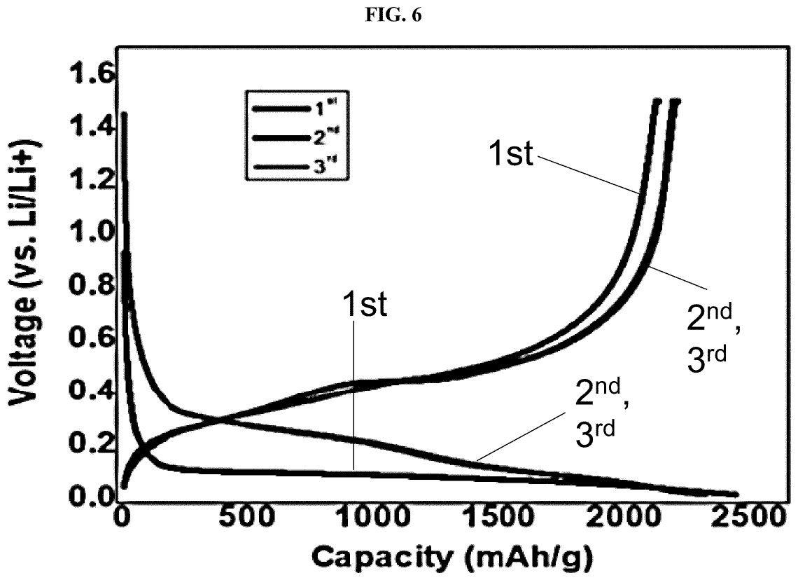

FIG. 6 is a plot of voltage potential (volts or V) as a function of capacity (in milliampere-hour per gram) showing the galvanostatic charge-discharge profiles of layered amorphous silicon oxycarbide (SiOC) films according to various embodiments. The voltage potential is measured with reference to a lithium/lithium ion (Li/Li⁺) reference electrode. The voltage profiles reveal the high reversible capacity behavior of monolayer amorphous film (MAF) coated active material, strongly suggesting Li ion diffusion through layered amorphous SiOC into the electrode material and the significant suppression of unstable and thick SEI growth, which is due to impermeability to other electrolyte products such as salts.

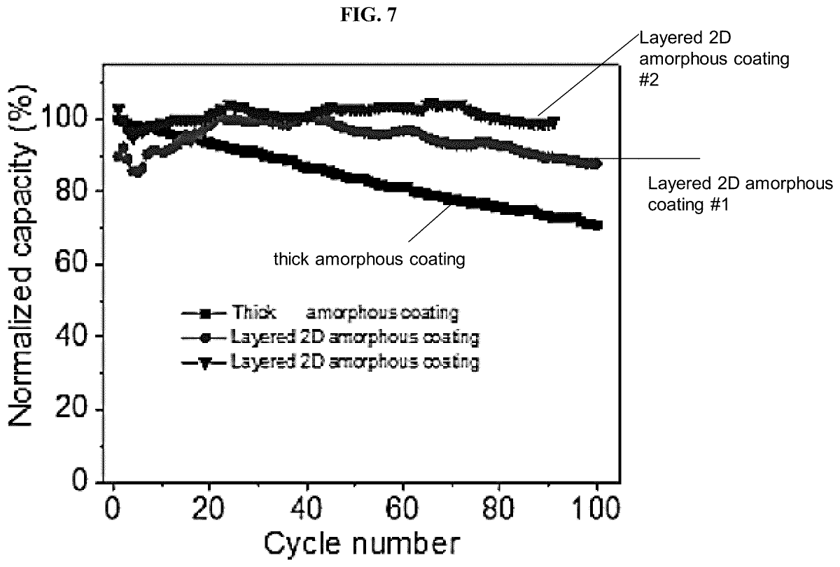

FIG. 7 is a plot of normalized capacity (in percent or %) as a function of cycle number illustrating the variation in capacities of a polymer-derived thick amorphous material coated active material particle as well as two layered two dimensional (2D) amorphous material particles according to various embodiments at a current density of 1 A/g over a potential range of 0.01 V to 1.5V according to various embodiments over time. The active material particle coated with thick 2D amorphous material shows rapid capacity decay to 70% of its initial value in less than 80 cycles due to pulverization and unstable SEI layer formation. For comparison, layered 2D amorphous material coated particles may show up to 25% improvement, suggesting the formation of stable-thin SEI layers due to selective ion permeability (i.e allowing diffusion of specific ion (Li ions in this example) into the inner active material particle but blocking percolation of other electrolyte products), and structural integrity of active material particles.

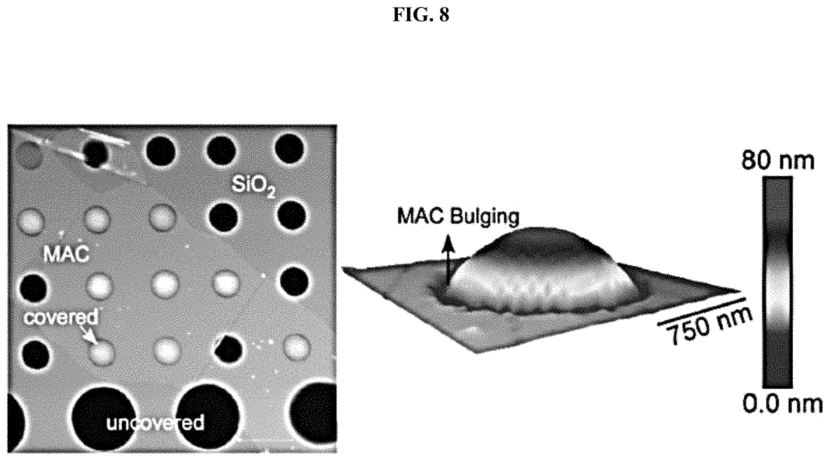

Selective barrier properties may be critical for selective ion permeability and impermeability to other electrolyte byproducts such as salts to replace existing unstable and time-consuming SEI growth mechanism. The bubble test is performed to evaluate MAC. FIG. 8 shows (left) an optical image of a bubble test in which some holes are covered by monolayer amorphous carbon (MAC) films according to various embodiments and gas is introduced such that the monolayer amorphous carbon (MAC) films each forms a bulge; and (right) an atomic force microscopy (AFM) image showing the bulging of the monolayer film according to various embodiments after removal from a high pressure gas chamber. The bubble forms by trapping pressurized gas, which suggests that atoms cannot pass through MAC, but only charge carrier ions, including but not limited to lithium ions (Li⁺), sodium ions (Na⁺), potassium ions (K⁺) can pass through MAFs. The bulging may remain even after 24 hours, indicating its effectiveness as a barrier material to gas atoms. MAFs may have the property of being highly engineered to allow preferential ion into the electrode, but at the same time limit the reactivity of the electrode with electrolytes. This may be critical to avoid or reduce any electrolyte decomposition, electrode-electrolyte side reaction, further SEI growth at the inner particle/layered atomically thin amorphous film interface, and any electrolyte salt composition on the surface of active material particle or at the interface, only allowing the diffusion of selective ions for high capacity and stability.

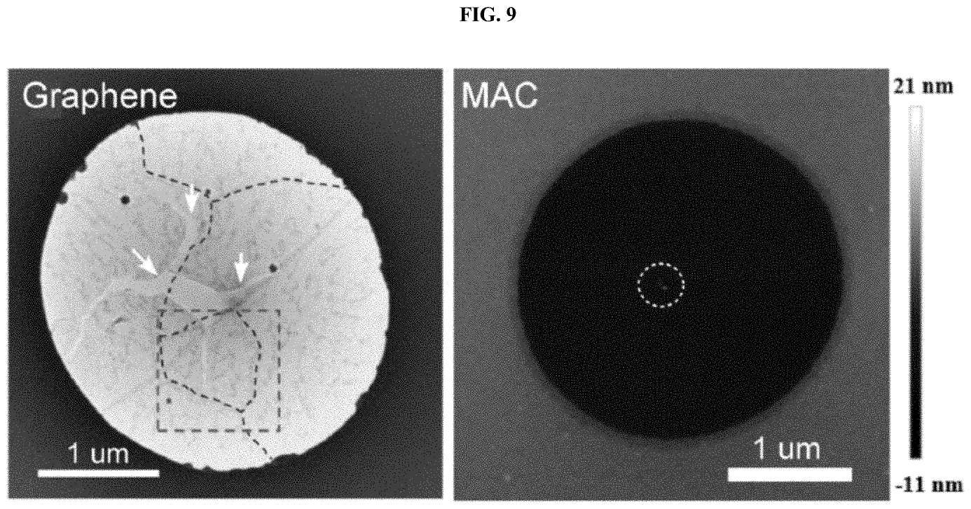

Nano mechanical properties may also be of great importance to battery electrodes. MAC may exhibit exceptionally high fracture toughness (xyz) attributed to its amorphous atomic structure with lack of grain boundaries, leading to crack-arresting phenomenon during fracture. MAC may also have significant plasticity. Under plastic deformation, carbon bonds may rearrange without breaking the barrier film, hence preventing failure. Even if a hole forms on the MAC film, the fracture may not propagate. This may be important for layered atomically thin amorphous films to accommodate large volume expansion of inner active material particles during insertion and extraction of ions. This may ensure the full coverage of MAFs on the surface of battery electrode materials during repeated cycling process. In contrast, for the crystalline counterpart (i.e. graphene), cracks may propagate along the preferred crystal directions or grain boundaries, diminishing the fracture toughness of the material. FIG. 9 shows (left) an optical image showing crack propagation along grain boundaries of graphene after indentation; and (right) an optical image of a monolayer amorphous carbon (MAC) film according to various embodiments showing lack of crack propagation after indentation. Similarly, other conventional coating materials may also be mechanically stiff and brittle, suggesting that these coatings will break rather than deforming plastically.

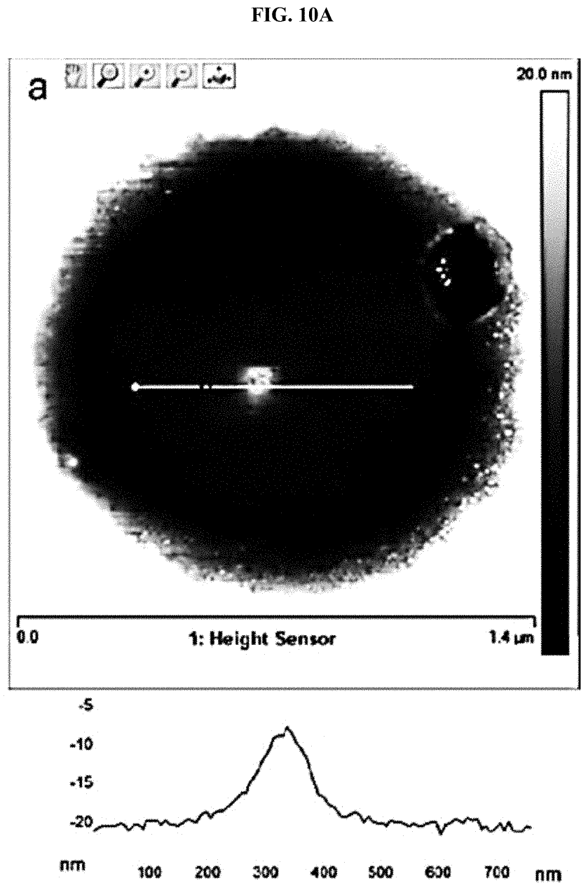

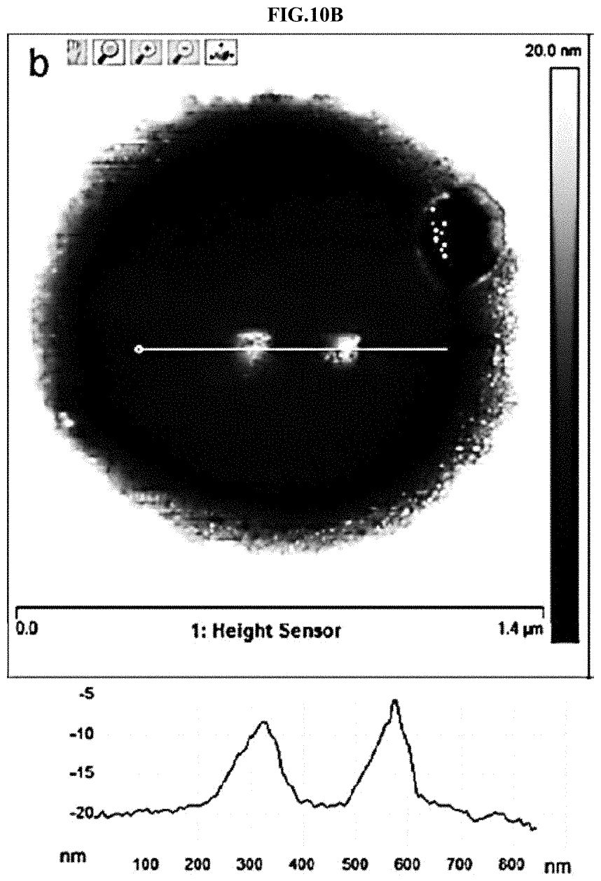

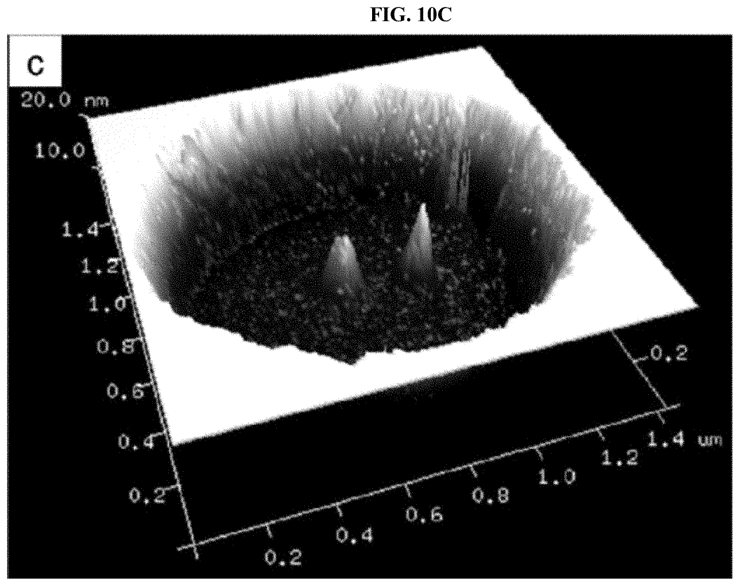

MAC may also exhibit high plasticity of >5% deformation without breaking, which is also critical to obtain a high fracture toughness. Significant plasticity has not been observed in conventional films previously. FIG. 10A shows (above) an atomic force microscopy (AFM) image of a suspended monolayer amorphous carbon (MAC) film according to various embodiments after an indentation is made on the film; and (below) a graph of height (in nanometers or nm) as a function of distance (in nanometers or nm) showing the corresponding height profile which shows an indentation peak after the AFM is pulled out of the monolayer amorphous carbon (MAC) film. FIG. 10B shows (above) another atomic force microscopy (AFM) image of the suspended monolayer amorphous carbon (MAC) film according to various embodiments after a second indentation is made on the film (on the right of the first indentation); and (below) a graph of height (in nanometers or nm) as a function of distance (in nanometers or nm) showing the corresponding height profile which shows a second indentation peak after the AFM is pulled out of the monolayer amorphous carbon (MAC) film. FIG. 10C shows a three-dimensional atomic force microscopy (AFM) image of the suspended monolayer amorphous carbon (MAC) film according to various embodiments with two indentations.

High fracture toughness may be key to endure high cycling stresses in a core-shell structure. Key features, including high plasticity, layered thin amorphous structure, and ion selectivity may be also critical to recognize monolayer amorphous films as stable artificial SEI layers, with distinct advantages compared to the naturally grown SEI layer, which is thick, highly brittle, and non-uniform.

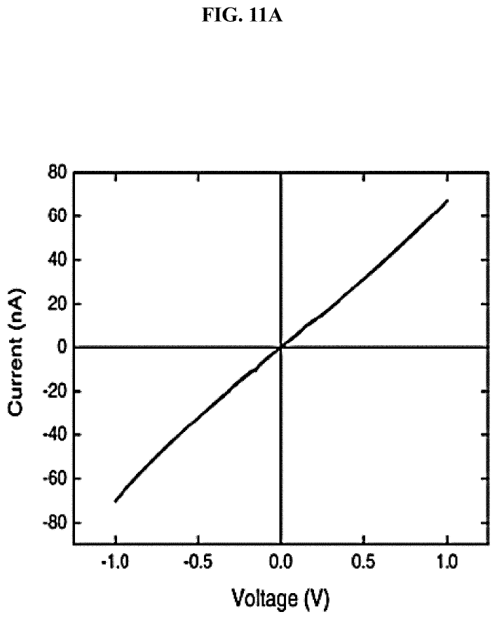

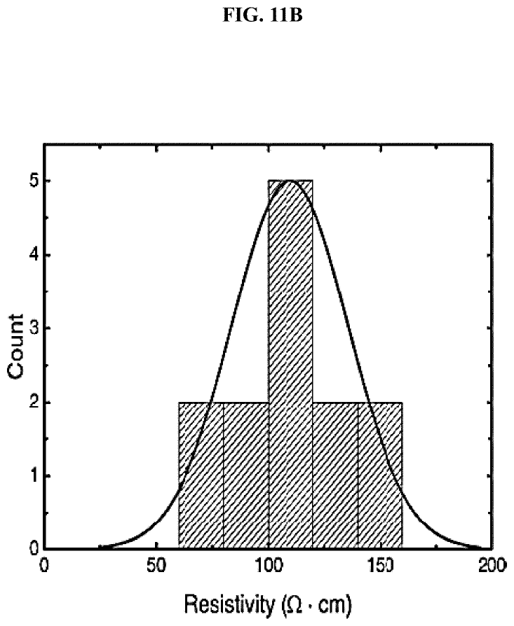

Depending on the crystallinity (C) value, monolayer amorphous carbon (MAC) may have an electrical resistivity value selected from a range from 0.01 Ω-cm to 1000 Ω-cm. A monolayer amorphous film (MAF) may have an electrical resistivity value selected from a range from 10² Ω-cm to 10¹⁰ Ω-cm. FIG. 11A is a plot of current (in amperes or A) as a function of voltage (V) showing the current-voltage (IV) curve of a monolayer amorphous film according to various embodiments. FIG. 11B is a plot of count (i.e. distribution) as a function of resistivity (in ohms-centimeters or a-cm) showing a histogram of the measured resistivity values for monolayer amorphous films of a particular crystallinity (C) value according to various embodiments.

For comparison, graphene, which is also used as coating material on active material particles, has a resistivity value of ˜10⁻⁶ Ω-cm. The higher electrical resistivity of atomically thin 2D amorphous film may block electrons from tunneling through to the surface of active material particle, thereby preventing further electrolyte reduction. This may ensure a much thinner and stable SEI layer formation. The ionically conducting and high electrical resistivity nature of MAFs may be of paramount importance to protect the electrolytes (both solid and liquid) from decomposition by active electrode materials, in particular cathode active materials at high potentials. Various embodiments may provide significant improvements in the capacity, high rate capability, cycle life of batteries, and may mitigate safety related risks.

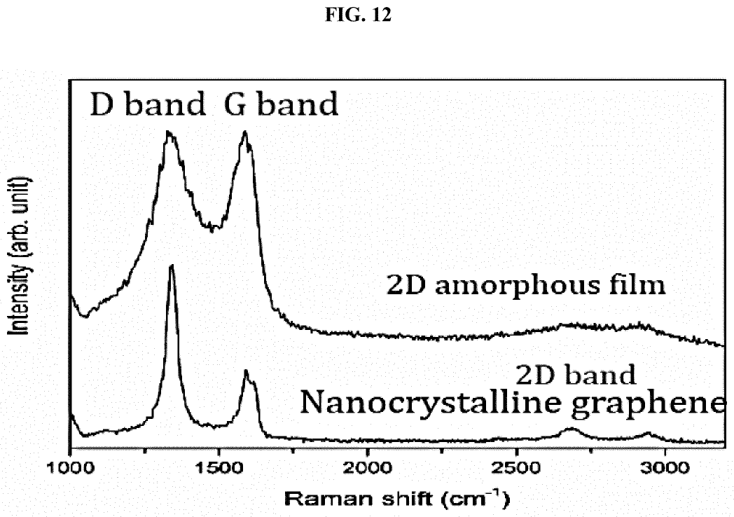

FIG. 12 is a plot of intensity (in arbitrary units) as a function of Raman shift (in per centimeter or cm⁻¹) showing the Raman spectra of a monolayer amorphous film according to various embodiments as well as nanocrystalline graphene. As shown in FIG. 12, Raman spectroscopy of the 2D amorphous film showed no 2D peak (˜2700 cm⁻¹) suggesting the absence of long-range order, but instead displayed broad G peak (at ˜1600 cm⁻¹) and D peak (at ˜1350 cm⁻¹). The broadening of D and G peaks usually indicates a transition from nanocrystalline graphene to amorphous film. The nanocrystalline graphene shows strong disorder mode of carbon (C) sp³ peak (D peak), while the 2D amorphous film has suppressed D peak. As previously reported discussed, dominance of sp³ peak may lead to brittle characteristics and may potentially result in local micro-crack failure of the active material particles.

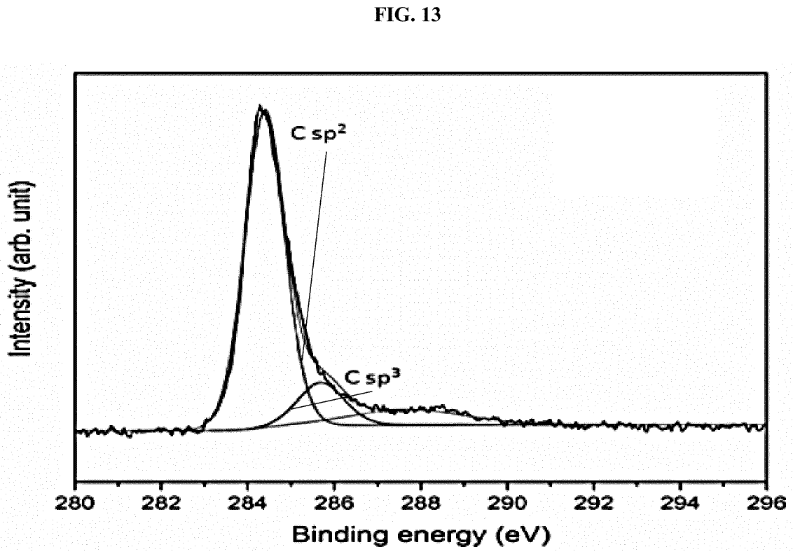

FIG. 13 is a plot of intensity (in arbitrary units) as a function of binding energy (in electron-volts or eV) showing the X-ray photoelectron spectroscopy (XPS) spectrum of an one atomic layer thick (6 Angstroms) amorphous film with a sp³/sp² ratio of 20% according to various embodiments. The thin layered structure may adhere strongly on the growth surface, and the elasticity of the film can effectively accommodate volume expansion of battery electrode materials for better cyclability during insertion and extraction of ions.

Unlike graphene on surfaces, which can be detached easily (adhesion force from 10-100 J/m²), various embodiments may adhere very well to the substrate with adhesion force greater than 200 J/m². The 2D amorphous films may provide full coverage on the surface of active materials at all times during repeated ion insertion and extraction to maintain structural integrity of the inner active material particle.

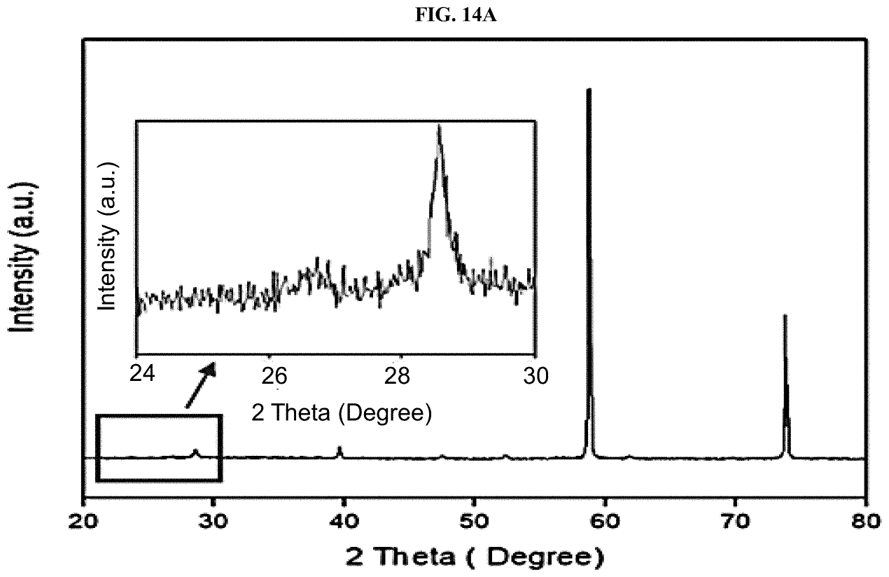

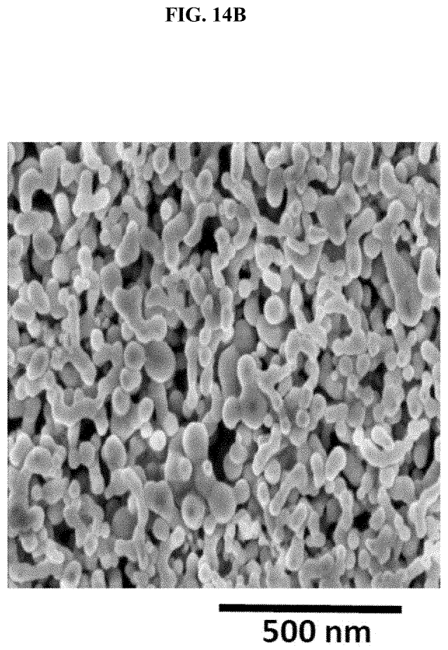

FIG. 14A is a plot of intensity (in arbitrary units) as a function of 2 Theta (in degrees) showing the X-ray diffraction (XRD) spectrum of a layered amorphous silicon oxycarbide (SiOC) film on an active material according to various embodiments, while the inset shows the amorphous characteristics of the layered amorphous silicon oxycarbide (SiOC) film. The active material is a silicon particle, which is used as an example. The X-ray diffraction (XRD) spectrum shows an amorphous characteristic of layered SiOC film combined with the crystalline Si. FIG. 14B is a scanning electron microscopy (SEM) image of layered amorphous silicon oxycarbide (SiOC) film coated active material particle according to various embodiments. The SEM image of layered amorphous film of SiOC highlights distinct contrast between the core and the entire shell, strongly suggesting the presence of the continuous layered amorphous film. The continuous layered amorphous film may protect the entire surface of the inner particle from electrolyte contact, thereby preventing or reducing the decomposition of the electrolyte into chemicals such as lithium fluoride (LiF) or sodium hydroxide (NaOH). The presence of layered amorphous SiOC, as one example of MAFs, on the shell may maintain structural integrity and may act as an artificial SEI layer contacting the electrolyte, and selectively allowing the diffusion of ions, leading to high capacity and a high durability electrode structure. The active material particle may expand to any value up to 425% during insertion and extraction of ions. The volume change before (V₁) and after (V₂) expansion may be calculated as follows:

$$\frac{{V}_{2}}{{V}_{1}} = ( \frac{4}{3} \times π {r}_{2}^{3} ) / ( \frac{4}{3} \times π {r}_{1}^{3} ) \qquad ( 1 )$$

V₂/V₁ may be up to 4.25. For example, silicon (Si) may undergo 400% volume expansion during lithiation, and tin (Sn), on the other hand, may expand up to 423% during sodiation and 360% during lithiation. Therefore, r₂/r₁ may be about 1.6. As such, in order to prevent strain-induced pulverization and failure, the provision of uniform and layered amorphous films with selective ion permeability may be critical. Various embodiments may endure this strain without fracture due to its elasticity, whereas previous reports showed that with thick amorphous coating, micro cracks may form where adhesion and uniformity are not sufficient and these cracks may propagate to the inner particle surface.

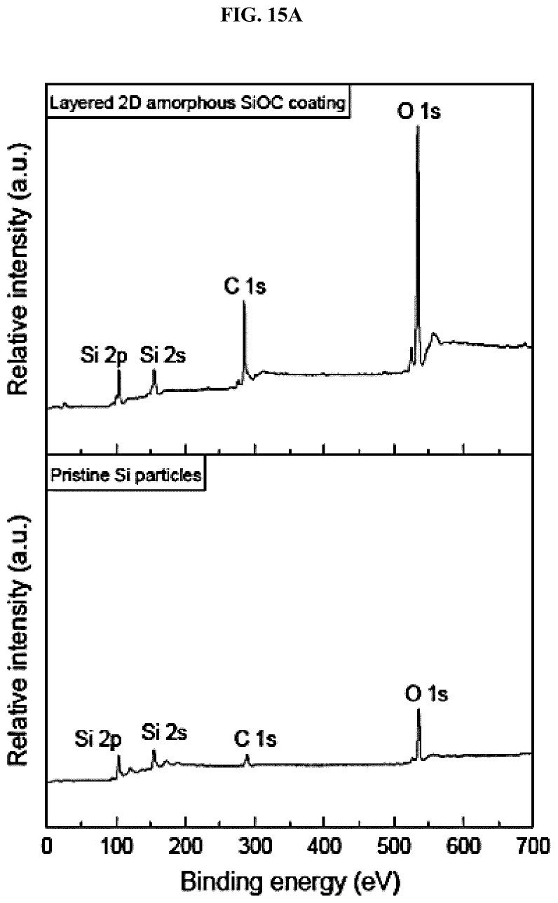

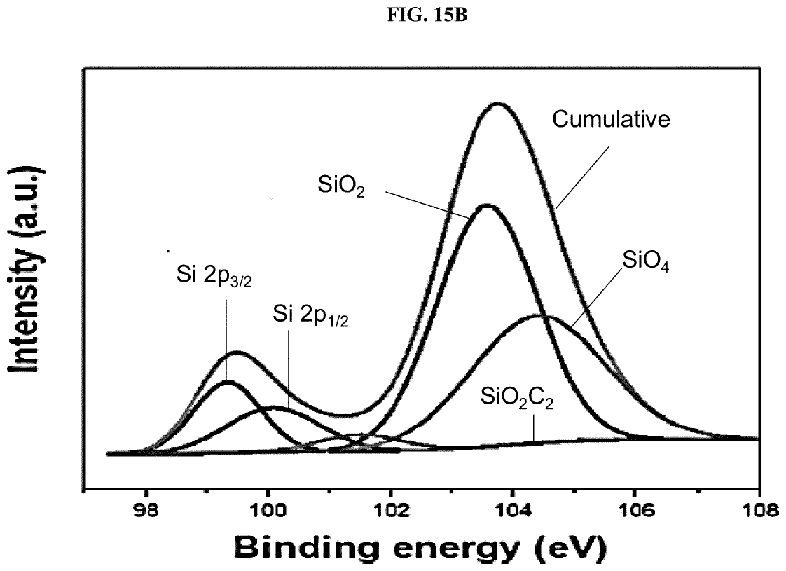

FIG. 15A shows (above) a plot of relative intensity (in arbitrary units or a.u.) as a function of binding energy (in electron volts or eV) illustrating the X-ray photoelectron spectroscopy (XPS) survey spectrum of a layered amorphous silicon oxycarbide (SiOC) film on a silicon (Si) particle; and (below) a plot of relative intensity (in arbitrary units or a.u.) as a function of binding energy (in electron volts or eV) illustrating the X-ray photoelectron spectroscopy (XPS) survey spectrum of pristine silicon (Si) particles. The survey scan XPS of pristine Si, as one example of active material particle, and MAF, of which layered amorphous SiOC is used as one example, show several distinct peaks. The increased peak intensities of C 1s at 283.8 eV, O 1s at 533.5 eV, and Si 2p at 100.5 eV suggest the presence of 2D amorphous SiOC coating on the surface of Si particle. The high resolution XPS in Si 2p region is deconvoluted to verify the presence layered amorphous SiOC films on active material particles, of which Si is used here as an example. The peak position at 101.8 eV corresponds to layered SiOC.

FIG. 15B is a plot of intensity (in arbitrary units or a.u.) as a function of binding energy (in electron volts or eV) illustrating high resolution deconvoluted X-ray photoelectron spectroscopy (XPS) spectrum of layered amorphous silicon oxycarbide (SiOC) film according to various embodiments in silicon (Si) 2p region.

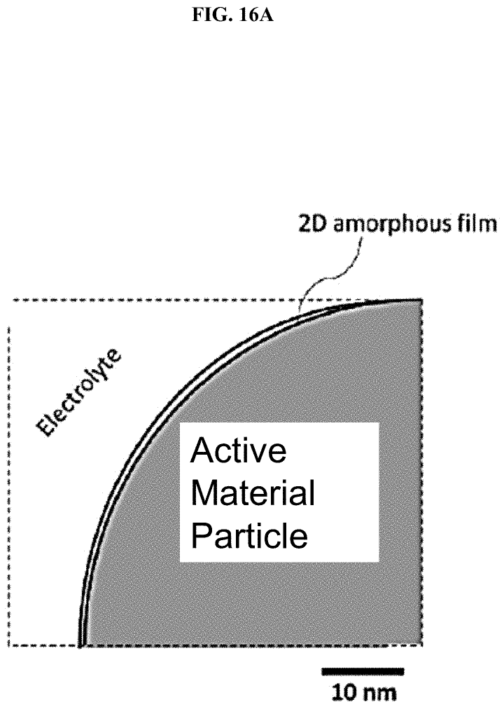

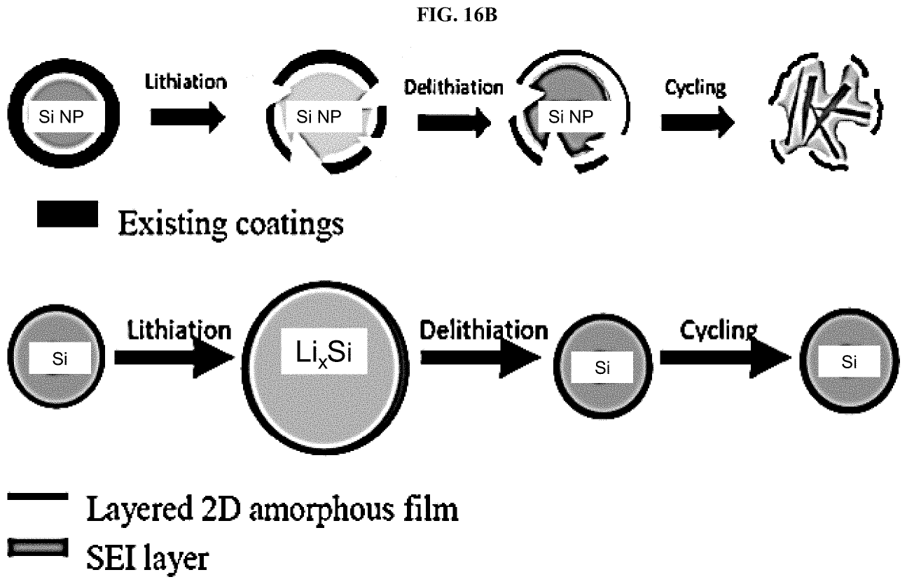

The combination of Raman, XPS, and XRD strongly suggests that the uniform growth of MAFs may be possible on the surface of arbitrary active material particles for both anode and cathode. FIG. 16A is a schematic illustrating a monolayer amorphous film according to various embodiments surrounding an active material particle according to various embodiments. FIG. 16B is a schematic depicting (above) a silicon active material particle coated with a conventional coating; and (below) a silicon active material particle coated with a monolayer amorphous film according to various embodiments under lithiation, delithiation and cycling. FIG. 16B highlights the pulverization, unstable SEI layer, and battery failure with thick coating. The active material particles with the monolayer amorphous film shows a stable and thin SEI layer, which benefits the integrity of active material particle during continuous cycling.

FIG. 16B depicts how monolayer amorphous films (MAFs) maintain the structural integrity of active electrode materials during cycling, which benefit from the selective ion permeability of the MAFs, the layered amorphous film structure, the mechanical and chemical stability, the full coverage of active material particles from direct electrolyte contact, and from the stable-thin SEI layer formation.

The silicon active material particle is highlighted as one example of an electrode material particle.

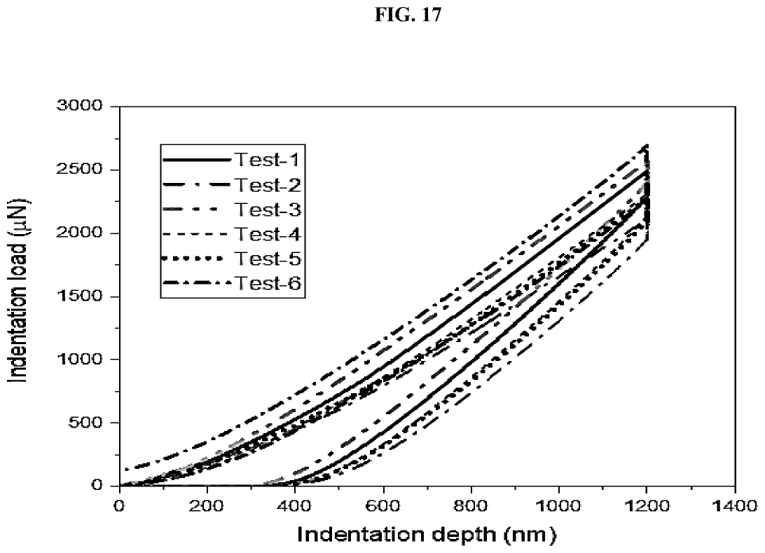

Precursor-derived SiOC coating with the thickness greater than 5 nm was reported to be subjected to strain induced cracking and pulverization due to high Young's modulus and lack of elasticity. FIG. 17 is a plot of indentation load (in micro-Newtons or μN) as a function of indentation depth (in nanometers or nm) shows the load-depth curves of a thick amorphous silicon oxycarbide (SiOC) film coating on active material particles. The thick amorphous silicon oxycarbide (SiOC) film coating has a relatively high Young's modulus of ˜2.6 GPa. For monolayer amorphous films, the Young's modulus may be much lower, in the range from 0.5 GPa to 1 GPa.

As mentioned earlier, the layered atomically thin 2D amorphous material in which sp³ to sp² ratio is between the range of 20%-0% may be used to coat active material particles. The range of elasticity indicated by Young's modulus from 0.5 GPa to 1 GPa may be critical to accommodate volume expansion of up to 400% of the inner active material particle. This may ensure adequate stretchability of the shell to accommodate volume expansion up to 400% during electrochemical cycling.

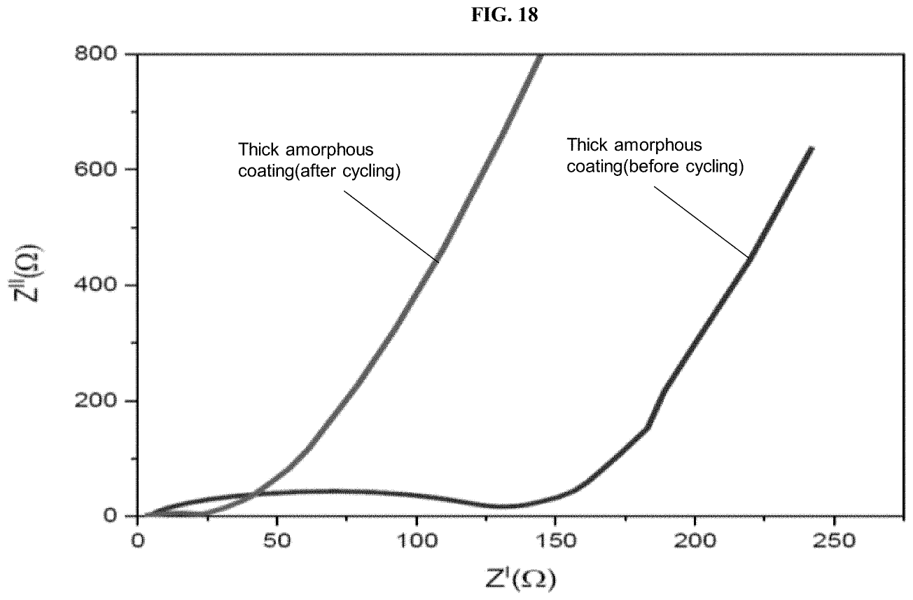

Electrochemical impedance spectroscopy (EIS) is an useful tool to evaluate charge transfer resistance and Li ion diffusion constant from its Warburg element. EIS was performed on thick (˜10 nm) SiOC coating before and after cycling, as shown in FIG. 18. FIG. 18 is a plot of the imaginary part of impedance (in ohms or Ω) as a function of the real part of impedance (in ohms or Ω) showing the electrochemical impedance spectroscopy (EIS) of a thick amorphous coating on active material particles. The charge transfer resistance of pristine alloying active material particles is in the range of 200Ω to 600Ω. The thick SiOC coating may lower the charge transfer resistance to only certain level because ion diffusion is limited by thick coating and unstable SEI layer. In contrast, various embodiments may reduce the charge transfer resistance to the range of 10 to 20Ω after cycling. This may benefit faster ion diffusion and may enable high C-rate capability for the resulting electrode material.

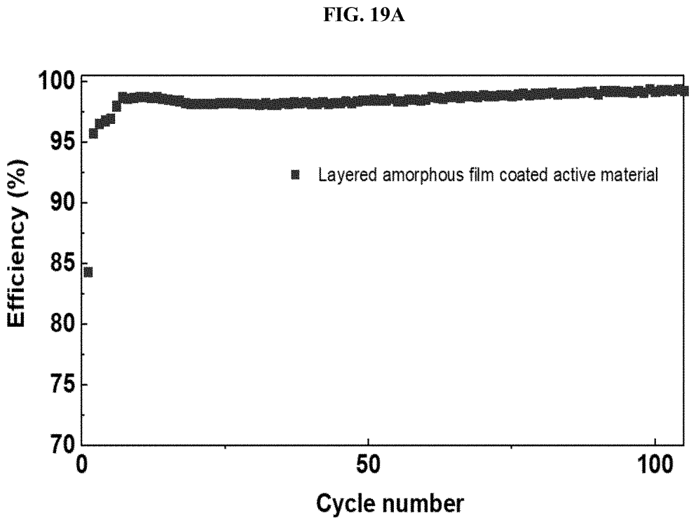

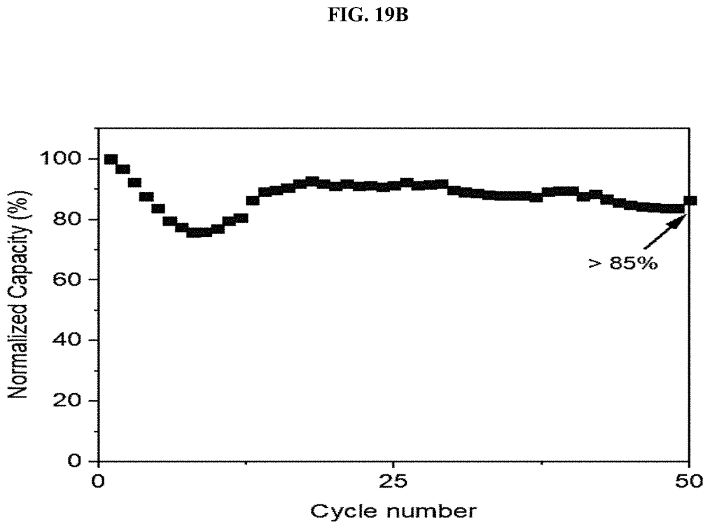

FIG. 19A is a plot of efficiency (in percent or %) as a function of cycle number illustrating the coulombic efficiency of the layered amorphous silicon oxycarbide (SiOC) coated electrode material according to various embodiments. The layered amorphous silicon oxycarbide (SiOC) coated electrode material may exhibit an initial coulombic efficiency of at least 84%. FIG. 19B is a plot of normalized capacity (in percent or %) as a function of cycle number illustrating the cycling stability of the layered amorphous film coated electrode material according to various embodiments. The layered amorphous film coated electrode material may exhibit cycling stability greater than 85% at 0.35C for 50 cycles.

Table 1 below illustrates features of monolayer amorphous films (MAFs) and their associated benefits/advantages:

| Feature | Benefit/Advantage |
|---|---|
| Permeable | MAFs can be engineered for selective ion permeability |
| only to | of various ions by a number of possible ways, |
| ionic | including tuning the ring structure of MAFs and |
| charge | layered structure. Based on the high density |
| carrier, | of > 6 member rings, ion diffusion may be better |
| imper- | than existing crystalline 2D materials, which are |
| meable | completely impermeable to most ion diffusion. Energy |
| to | requirements for ionic diffusion through a certain ring |
| electrolyte/ | size may be reduced by functionalization. MAFs can |
| gases | be functionalized (e.g. functionalization of the pore |
| | with atoms such as nitrogen (N), fluorine (F), boron |
| | (B), oxygen (O), chlorine (Cl)) to tune its properties |
| | (e.g. ionic transport, selectivity, conductivity). The |
| | monolayer amorphous films are permeable to |
| | only ionic charge carriers such as lithium ions |
| | (Li⁺), sodium ions (Na⁺), potassium ions (K⁺) so that |
| | no electrode active material is lost to unwanted |
| | secondary reactions. Simultaneously, MAFs may be |
| | impermeable to electrolyte molecules such as salts and |
| | gases. This is essential to prevent or reduce the |
| | migration of electrolyte molecules and gases through |
| | MAFs to the inner active material, thereby |
| | suppressing brittle and thick SEI growth. In existing |
| | manufacturing process, SEI growth is carried out in |
| | time consuming and expensive ways, and the resulting |
| | SEI growth is still non-uniform and has random crack- |
| | like channels which has poor selectivity. |
| | Therefore, the existing SEI gives rise to uneven ion |
| | diffusion into the electrode, and more importantly |
| | allow considerable amount of diffusion of other |
| | electrolyte molecules onto the surface of electrode |
| | materials, which leads to battery failure due to |
| | pulverization as these electrolyte molecules (salt and |
| | solvent) are reduced on the surface of active |
| | material forming a unstable thick coating of |
| | mixture of inorganic (e.g. lithium fluoride (LiF), |
| | phosphoryl fluoride (POF)) and organic species. |
| | Conventionally, SEI is formed in-situ of the |
| | batteries before batteries leave the production |
| | line. This is known as battery formation process, |
| | and it consumes active electrode materials, |
| | electrolyte, and also time. MAFs are |
| | permeable to selective charge |
| | carrier ions only, meaning that |
| | MAFs may allow the diffusion of |
| | only selective ions but may |
| | block the percolation of other |
| | electrolyte molecules. Hence, |
| | various embodiments may be |
| | effective in limiting solvent reduction, |
| | electrolyte-electrode side |
| | reactions to suppress electrode |
| | pulverization, salt formation around |
| | the surface of active material |
| | particles. The use of MAFs may |
| | eliminate the requirement of the |
| | battery formation process. This |
| | process is required for performance |
| | stability but reduces the overall |
| | battery performance and is |
| | time consuming. MAF may have an |
| | amorphous structure with ring |
| | diameters of 2.8 Angstrom to 23 |
| | Angstrom, and may be |
| | selective to ionic charge carriers. |
| Low sp³ | Existing attempts to stabilize SEI |
| to sp² | growth have been largely focused |
| ratio | on coating the surface with thick |
| | amorphous carbon or amorphous |
| | SiOC, where sp³ to sp² ratio |
| | is high, typically in the range of 60%- |
| | 80%. These approaches have not |
| | solved the stability issue yet. |
| | MAFs with high sp² ratio could |
| | come in many forms, including |
| | monolayer amorphous carbon and |
| | monolayer amorphous mixed |
| | bond Si-C-O (i.e.SiOC) to allow |
| | only specific ions to go through. |
| | MAFs may include sp²-bonded |
| | carbon with thickness of only one |
| | atomic layer thick, thinner than |
| | any reported amorphous carbon |
| | due to the different structure. |
| | Various embodiments may have |
| | sp³/sp² carbon ratio of 0% to 20%. |
| | It has been reported that existing |
| | amorphous films are stiff and |
| | more brittle when sp³ to sp² ratio is |
| | high. With low sp³ to sp² ratio, |
| | various embodiments may show |
| | elastic characteristic, which is of |
| | great importance to maintain long |
| | battery lifetime. |
| Layered | Existing carbon coatings on |
| structure | electrode materials are thick (around |
| | 10 nm) and have poor elasticity, |
| | leading to rapid degradation |
| | during repeated volume expansion. |
| | This causes fracture of active |
| | material particles during early |
| | battery charge cycles, contributing |
| | to chronic battery capacity fading |
| | issues. Layered structure of 2D |
| | amorphous materials in various |
| | embodiments may enable |
| | sufficient elasticity for volume |
| | expansion of active materials. |
| | Moreover, a coating including |
| | the layered structure 2D amorphous |
| | material with a range of thickness from |
| | 0.3 nm to 1.2 nm may be |
| | beneficial for efficient diffusion |
| | of charge carriers, compared to |
| | thick amorphous carbon coating, |
| | where charge carrier diffusion is limited. |
| Uniform | The layered amorphous films in |
| coating | various embodiments may form a |
| | uniform coating that is continuous |
| | over the entire surface. This |
| | evenly distributes stress-strain on |
| | inner active material particle. |
| | Existing polymer-derived carbon |
| | and CVD growth carbon have |
| | failed to achieve uniform coating |
| | on the particles. Similarly, atomic |
| | layer deposition (ALD) typically |
| | result in island nucleation growth, |
| | so the uniformity of coatings of |
| | metal oxide formed by ALD cannot |
| | be achieved. These non-uniform |
| | coatings result in uneven volume |
| | expansion and subsequent capacity |
| | fading due to pulverization of |
| | active material particles. |
| | Various embodiments may involve |
| | layered amorphous film growth |
| | at the atomic scale, thereby |
| | resulting in the uniformity and |
| | continuity of 2D amorphous films |
| | formed. This may be of great |
| | benefit in suppressing volume |
| | expansion and protecting inner |
| | particles of active materials |
| | from direct contact with the electrolyte, |
| | thereby avoiding or reducing |
| | electrode-electrolyte side reactions. |
| Elasticity | The elasticity of 2D amorphous |
| and | coating prevents inner active |
| plasticity | material particle from cracking |
| | and pulverization, thereby |
| | maintaining electrode structural |
| | integrity against volume |
| | expansion. MAF is the first 2D |
| | material to show significant |
| | plasticity, such that the structure |
| | can deform without breaking. This |
| | is a key benefit for batteries when |
| | active materials expand during |
| | lithiation with no breaking or |
| | pulverization. MAC has more than |
| | 5× lower Young's modulus than |
| | graphene, indicating higher |
| | flexibility. This feature is important |
| | for batteries when active |
| | materials shrink during delithiation. |
| | Other coatings such as |
| | polymer-derived carbon coating |
| | and metal oxides (e.g. Al₂O₃, |
| | ZrO₂) are brittle and hence they |
| | are not effective to suppress |
| | electrode pulverization caused by |
| | volume expansion of active |
| | material. Furthermore, the existing |
| | approaches are not feasible for |
| | mass production because these |
| | coating layers could break during |
| | harsh slurry mixing and electrode |
| | calendaring processes. The two- |
| | dimensional equivalent form of |
| | carbon is graphene, however, |
| | graphene only exists in a crystalline |
| | form, either polycrystalline or |
| | single crystal. Graphene cracks |
| | along the crystal plane or along |
| | grain boundaries, with the cracks |
| | rapidly propagating under stress. |
| Low | The coating of MAFs around active |
| temper- | material particles may be |
| ature | formed by spark plasma sintering |
| growth | (SPS) of a carbonaceous or |
| | silicon containing polymeric |
| | precursor on the surface of silicon |
| | particles or by direct deposition |
| | using gas precursors. The growth |
| | temperature may be ≤ 500° C.. |
| | In comparison, thermal |
| | decomposition of polymeric |
| | precursors or direct growth of |
| | crystalline graphene as a shell |
| | on the particles requires |
| | temperatures up to 1000° C.. |
| | Thermal decomposition of polymerix |
| | precursors and direct growth of |
| | graphene give rise to the formation |
| | of metal-ceramic composites |
| | at the core-shell interface. Such |
| | metal-ceramic composites have |
| | a low ionic and electronic |
| | conductivity, and their presence |
| | at the interface may limit ionic |
| | diffusion into the active materials |
| | and may significantly lower the |
| | capacity of the active material. To |
| | this end, a challenge of growing |
| | 2D amorphous films directly on |
| | electrode materials have been |
| | overcome. The 2D amorphous |
| | film may be grown without the |
| | metal-ceramic formation using temperatures ≤ |
| | 500° C. at a much faster speed. |
| In-plane | Unlike polycrystalline graphene, |
| electrically | MAFs may not be crystalline. For |
| insulating | monolayer amorphous carbon (MAC), |
| | which is one example of |
| | MAFs, this may result in the |
| | formation of an electrically insulating |
| | film with sheet resistance values in the |
| | order of 1GΩ/□ to 10TΩ/□. |
| | Alternatively, similar resistivity |
| | can be obtained with monolayer |
| | amorphous boron nitride. Continuous |
| | unstable SEI growth is |
| | induced by porous SEI or radical |
| | electron transfer, causing |
| | electrolyte reduction reaction. |
| | Hence, in order for films to protect |
| | the electrolyte from further |
| | reduction/decomposition for thin-stable |
| | SEI layer, the films should block |
| | electron tunneling. Various |
| | embodiments may serve as an |
| | artificial SEI layer to prevent further |
| | electrolyte decomposition at the |
| | surface of active materials by |
| | blocking electron tunneling. |
| | The electrically resistance of the films |
| | may be required to be within the |
| | range of 10GΩ to 500GΩ in order |
| | to effectively block the passage |
| | of electrons and thus to suppress |
| | further decomposition reactions of |
| | the electrolyte with electrode |
| | surfaces. Accordingly, this may |
| | suppress the further degradation of |
| | electrode materials and may also |
| | prevent the consumption of |
| | charge carrier ions in the electrolyte, |
| | thereby improving the |
| | stability and reversibility of the batteries. |
| Strong | The thin structure and strong adhesion |
| adhesion | of 2D amorphous films may |
| on the | intrinsically protect the whole |
| surface | electrode surface all the time, unlike |
| | in thicker films where flaking off is |
| | inevitable. The strong adhesion |
| | of 2D amorphous films may endure |
| | volume expansion of the active |
| | material particles to maintain structural |
| | integrity of the electrode. |

SEI is the key structural component of battery electrodes which significantly impacts on the power capability, safety, morphology of lithium deposits, specific capacity of battery electrodes, and cycle life of batteries. MAFs may be needed as a coating on high capacity active materials to stabilize the SEI layer. MAFs may also significantly improve battery performance due to its unique properties, including atomic selectivity, selective diffusion of ions such as Li⁺, Na⁺, K⁺, layered atomically thin structure, impermeability to other electrolyte products such as salts, high strength, high fracture toughness and plasticity, exceptionally high tolerance to expansion and contraction stresses during charging and discharging, stability over a range of operating temperatures and potentials, and insolubility in the electrolyte. MAFs have the property of both high electrical resistivity and ionically conductivity, thus allowing MAFs to significantly protect the electrolytes (both liquid and solid) from decomposition by the active materials at high voltages, which in turn allows batteries to practically achieve capacities close to theoretical values with up to 3 times enhanced cycle life. Existing solutions do not have these critical material properties, and hence initial specific capacities of the active materials are still well below their theoretical values, which may then lead to significant capacity loss of up to 50% of the initial value within the range of 100 cycles to 150 cycles due to a thick layer of SEI that provides a constraint to the active material particles from swelling upon lithiation and leads to pulverized and disconnected particles. Compared to existing solutions, various embodiments including monolayer amorphous films may improve battery cycling stability of up to 600 cycles by maintaining 75%-90% of their initial specific capacity. Various embodiments may achieve very high specific capacities ranging from 1800 mAh/g to 2500 mAh/g with high cycling stability, which is almost 2.5 times the specific capacities of existing solutions. Compared to existing solutions where charge transfer resistance is higher than 200Ω, the charge transfer resistance involving monolayer amorphous films may be significantly reduced to values between range of 10Ω to 20Ω, with no observable impedance increase due to the stable and thin SEI layer. The significant reduction in charge transfer resistance may benefit high cycling rate capabilities at current densities up to 10 A/g for delivering higher power density of batteries.

Embodiments may include, but are not limited to the following:

(A) An electrode including an electrode core including an electrode active material; and one or more monolayer amorphous films; wherein each of the one or more monolayer amorphous films is a continuous layer surrounding the electrode core.

(B) The electrode according to statement (A), wherein the electrode active material is an anode active material.

(C) The electrode according to statement (B), wherein the anode active material is any one material selected from a group consisting of silicon, tin, aluminum, and germanium.

(D) The electrode according to statement (A), wherein the electrode active material is a cathode active material.

(E) The electrode according to statement (D), wherein the cathode active material is any one material selected from a group consisting of lithium cobalt oxide (LiCoO₂), lithium manganese oxide (LiMn₂O₄), lithium nickel cobalt manganese oxide (LiNiMnCoO₂), lithium iron phosphate (LiFePO₄), lithium nickel cobalt aluminum oxide (LiNiCoAlO₂), and lithium nickel manganese cobalt oxide (LiNiCoMnO₂).

(F) The electrode according to any one of statements (A) to (E), wherein a ratio of a number of hexagonal carbon rings to a total number of hexagonal carbon rings and non-hexagon carbon rings present in the one or more monolayer amorphous films is equal to 0.8 or less.

(G) The electrode according to statement (F), wherein an average diameter of the hexagonal carbon rings is any value selected from a range from 0.76 Angstroms to 2.3 Angstroms; and wherein an average diameter of the non-hexagonal carbon rings is any value selected from a range from 0.76 Angstroms to 2.3 Angstroms.

(H) The electrode according to any one of statements (A) to (G), wherein each of the one or more monolayer amorphous films include in-plane bonds.

(I) The electrode according to any one of statements (A) to (H), wherein the one or more monolayer amorphous films have a thickness of a value selected from a range from 0.3 nm to 3 nm.

(J) The electrode according to any one of statements (A) to (I), wherein the one or more monolayer amorphous films have an electrical resistivity of a value selected from a range from 10⁻² Ωcm to 10³ Ωcm.

(K) The electrode according to any one of statements (A) to (J), wherein the one or more monolayer amorphous films are configured to withstand up to a percentage deformation selected from a range from 1% to 20% without fracturing.

(L) The electrode according to any one of statements (A) to (K), wherein a bond ratio of sp² bonds to a total number of sp² and sp³ bonds present in the one or more monolayer amorphous films is 0.8 or greater.

(M) The electrode according to any one of statements (A) to (L), wherein the one or more monolayer amorphous films have a Young Modulus of a value selected from a range from 50 GPa to 500 GPa.

(N) The electrode according to any one of statements (A) to (M), wherein an adhesion force of the one or more monolayer amorphous films to a surface of the electrode core is of a value greater or equal to 200 Jm⁻².

(O) The electrode according to any one of statements (A) to (N), wherein the one or more monolayer amorphous films are monolayer amorphous carbon (MAC) films, layered amorphous silicon oxycarbide (SiOC) films, or layered amorphous silicon carbon nitride (SiCN) films.

(P) The electrode according to any one of statements (A) to (N), wherein the one or more monolayer amorphous films include one or more monolayer amorphous carbon (MAC) films and one or more layered amorphous silicon oxycarbide (SiOC) films; and wherein the one or more monolayer amorphous carbon (MAC) films form an alternating stack arrangement with the one or more layered amorphous silicon oxycarbide (SiOC) films.

(Q) The electrode according to any one of statements (A) to (P), wherein the one or more monolayer amorphous films include a plurality of monolayer amorphous films.

(R) The electrode according to statement (Q), wherein a structure of a first monolayer amorphous film of the plurality of monolayer amorphous films is different from a structure of a second monolayer amorphous film of the plurality of monolayer amorphous films.

(S) The electrode according to statement (R), wherein a property of the first monolayer amorphous film of the plurality of monolayer amorphous films is different from a property of the second monolayer amorphous film of the plurality of monolayer amorphous films.

(T) The electrode according to any one of statements (A) to (S), wherein the electrode is configured to exhibit an initial coulombic efficiency of at least 84%.

(U) The electrode according to any one of statements (A) to (T), wherein the electrode is configured to exhibit cycling stability greater than 85% at 0.35 C for 50 cycles.

(V) An electrochemical cell including an electrode according to any one of statements (A) to (U); a further electrode; and an electrolyte in contact with the electrode and the further electrode.

(W) The electrochemical cell according to statement (V), wherein the further electrode includes a further electrode core comprising a further electrode active material; and one or more further monolayer amorphous films; and wherein each of the one or more further monolayer amorphous films is a continuous layer surrounding the further electrode core.

(X) A method of forming an electrode, the method including forming an electrode core including an electrode active material; and forming one or more monolayer amorphous films; wherein each of the one or more monolayer amorphous films is a continuous layer surrounding the electrode core.

(Y) A method of forming an electrochemical cell, the method including forming an electrode according to any one of statements (A) to (U); providing a further electrode; and providing an electrolyte in contact with the electrode and the further electrode.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. An electrode comprising:
an electrode core comprising an electrode active material; and
one or more monolayer amorphous films;
wherein each of the one or more monolayer amorphous films is a continuous layer surrounding the electrode core.

2. The electrode according to claim 1,
wherein the electrode active material is an anode active material.

3. The electrode according to claim 2,
wherein the anode active material is any one material selected from a group consisting of silicon, tin, aluminum, and germanium.

4. The electrode according to claim 1,
wherein the electrode active material is a cathode active material, and optionally, wherein the cathode active material is any one material selected from a group consisting of lithium cobalt oxide (LiCoO₂), lithium manganese oxide (LiMn₂O₄), lithium nickel cobalt manganese oxide (LiNiMnCoO₂), lithium iron phosphate (LiFePO₄), lithium nickel cobalt aluminum oxide (LiNiCoAlO₂), and lithium nickel manganese cobalt oxide (LiNiCoMnO₂).

5. (canceled)

6. The electrode according to claim 1,
wherein a ratio of a number of hexagonal carbon rings to a total number of hexagonal carbon rings and non-hexagon carbon rings present in the one or more monolayer amorphous films is equal to 0.8 or less, and optionally, wherein an average diameter of the hexagonal carbon rings is any value selected from a range from 0.76 Angstroms to 2.3 Angstroms; and
wherein an average diameter of the non-hexagonal carbon rings is any value selected from a range from 0.76 Angstroms to 2.3 Angstroms.

7. (canceled)

8. The electrode according to claim 1,
wherein each of the one or more monolayer amorphous films comprise in-plane bonds.

9. The electrode according to claim 1,
wherein the one or more monolayer amorphous films have a thickness of a value selected from a range from 0.3 nm to 3 nm.

10. The electrode according to claim 1,
wherein the one or more monolayer amorphous films have an electrical resistivity of a value selected from a range from 10⁻² Ωcm to 10³ Ωcm.

11. The electrode according to claim 1,
wherein the one or more monolayer amorphous films are configured to withstand up to a percentage deformation selected from a range from 1% to 20% without fracturing.

12. The electrode according to claim 1,
wherein a bond ratio of sp² bonds to a total number of sp² and sp³ bonds present in the one or more monolayer amorphous films is 0.8 or greater.

13. The electrode according to claim 1,
wherein the one or more monolayer amorphous films have a Young Modulus of a value selected from a range from 50 GPa to 500 GPa.

14. The electrode according to claim 1,
wherein an adhesion force of the one or more monolayer amorphous films to a surface of the electrode core is of a value greater or equal to 200 Jm⁻².

15. The electrode according to claim 1,
wherein the one or more monolayer amorphous films are monolayer amorphous carbon (MAC) films, layered amorphous silicon oxycarbide (SiOC) films, or layered amorphous silicon carbon nitride (SiCN) films.

16. The electrode according to claim 1,
wherein the one or more monolayer amorphous films comprise one or more monolayer amorphous carbon (MAC) films and one or more layered amorphous silicon oxycarbide (SiOC) films; and
wherein the one or more monolayer amorphous carbon (MAC) films form an alternating stack arrangement with the one or more layered amorphous silicon oxycarbide (SiOC) films.

17. The electrode according to claim 1,
wherein the one or more monolayer amorphous films comprise a plurality of monolayer amorphous films, and optionally, wherein a structure of a first monolayer amorphous film of the plurality of monolayer amorphous films is different from a structure of a second monolayer amorphous film of the plurality of monolayer amorphous films, and optionally, wherein a property of the first monolayer amorphous film of the plurality of monolayer amorphous films is different from a property of the second monolayer amorphous film of the plurality of monolayer amorphous films.

18. (canceled)

19. (canceled)

20. The electrode according to claim 1,
wherein the electrode is configured to exhibit an initial coulombic efficiency of at least 84%.

21. The electrode according to claim 1,
wherein the electrode is configured to exhibit cycling stability greater than 85% at 0.35 C for 50 cycles.

22. An electrochemical cell comprising:
an electrode according to claim 1;
a further electrode; and
an electrolyte in contact with the electrode and the further electrode;
and optionally,
wherein the further electrode comprises:
a further electrode core comprising a further electrode active material; and
one or more further monolayer amorphous films; and
wherein each of the one or more further monolayer amorphous films is a continuous layer surrounding the further electrode core.

23. (canceled)

24. A method of forming an electrode, the method comprising:
forming an electrode core comprising an electrode active material; and
forming one or more monolayer amorphous films;
wherein each of the one or more monolayer amorphous films is a continuous layer surrounding the electrode core.

25. A method of forming an electrochemical cell, the method comprising:
forming an electrode according to claim 1;
providing a further electrode; and
providing an electrolyte in contact with the electrode and the further electrode.
